(19) United States
(12) Patent Application Publication
(10) Pub. No.: US 2026/0227490 A1
(43) Pub. Date: Aug. 6, 2026

(54) LIDAR DEVICE INCLUDING WINDOW MODULE

(71) Applicant: SOS LAB Co., Ltd., Gwangju (KR)

(72) Inventors: Hoonil JEONG, Gwangju-si Gyeonggi-do (KR); Chan M LIM, Yongin-si Gyeonggi-do (KR); Bumsik WON, Anyang-si Gyeonggi-do (KR); Gyeonghwan SHIN, Gwangju (KR); Sungyong YOON, Seoul (KR)

(73) Assignee: SOS LAB Co., Ltd., Gwangju (KR)

(21) Appl. No.: 19/578,155

(22) Filed: Mar. 25, 2026

Related U.S. Application Data
(63) Continuation of application No. PCT/KR2024/013379, filed on Sep. 5, 2024.

(30) Foreign Application Priority Data
Sep. 26, 2023 (KR) 10-2023-0128694

(51) Int. Cl. G01S 7/481

(52) U.S. Cl. CPC G01S 7/4813; G01S 7/4817

(57) ABSTRACT

Proposed is a LiDAR device including: a transmission module including a laser emitting array and a transmission optic, wherein the transmission optic includes a first optical axis and a transmission entrance pupil; a reception module including a laser detecting array and a reception optic, wherein the reception optic includes a second optical axis; a case configured to accommodate at least a portion of the transmission module and at least a portion of the reception module; and a window module configured to provide an internal space for accommodating the transmission optic and the reception optic when combined with the case.

### CROSS-REFERENCE TO RELATED APPLICATIONS

This application is a continuation of International Application No. PCT/KR2024/013379 filed on September 5, 2024, which claims priority to Korean Patent Application No. 10-2023-0128694 filed on September 26, 2023, the entire contents of which are herein incorporated by reference.

### TECHNICAL FIELD

[1] The present disclosure relates to a LiDAR device. More particularly, the present disclosure relates to a LiDAR device including a window module.

### BACKGROUND ART

[2] Recently, along with interest in autonomous vehicles and unmanned vehicles, light detection and ranging (LiDAR) has been in the spotlight. LiDAR is a device for acquiring surrounding distance information using a laser. Due to LiDAR’s advantages such as excellent precision and resolution and the ability to detect objects in 3D, LiDAR is increasingly applied to various fields such as automobiles, drones, and aircraft.

[3] In the meantime, a solid-state-LiDAR device is a device capable of acquiring distance information for a 3D surrounding space without a mechanically moving configuration.

[4] As such a LiDAR device is utilized in various industrial fields, the LiDAR device needs to be manufactured to satisfy requirements demanded in the industrial fields, such as waterproof/dustproof requirements. To this end, the LiDAR device may be provided in a configuration including a window module so as to enable distance measurement while making the internal configuration of the LiDAR device airtight.

[5] However, when a conventional flat window module is used in a solid-state-LiDAR device, problems such as a back-beam phenomenon, degradation of minimum detection distance performance, and degradation of maximum detection distance performance may occur.

[6] Accordingly, there is a need for the development of a LiDAR device capable of solving the aforementioned problems.

### SUMMARY

### Technical Problem

[7] The present disclosure is directed to providing a LiDAR device in which a back-beam phenomenon is solved.

[8] Technical problems to be solved by the present disclosure are not limited to the aforementioned technical problems and other technical problems which are not mentioned will be clearly understood by those skilled in the art from the present specification and the accompanying drawings.

### Technical Solution

[9] According to an embodiment of the present disclosure, a LiDAR device may be provided comprising : a transmission module comprising a laser emitting array and a transmission optic, wherein the transmission optic comprises a first optical axis and a transmission entrance pupil; a reception module comprising a laser detecting array and a reception optic, wherein the reception optic comprises a second optical axis; a case configured to accommodate at least a portion of the transmission module and at least a portion of the reception module; and a window module configured to provide an internal space for accommodating the transmission optic and the reception optic when combined with the case; wherein the window module comprises a first optical window that allows light emitted from the transmission module to exit from the internal space, and a second optical window that allows light to be received by the reception module to enter the internal space, wherein a first laser emitting unit included in the laser emitting array is configured to emit a first laser, wherein the first laser emitting unit is disposed in a central region of the laser emitting array, wherein the first laser passes through a first region of the first optical window, wherein a second laser emitting unit included in the laser emitting array is configured to emit a second laser, wherein the second laser emitting unit is disposed at an edge of the laser emitting array, wherein a second region of the first optical window is curved, and wherein a radius of curvature of the first region is greater than a distance between the transmission entrance pupil and the first region.

However, the means for solving the problems of the present disclosure are not limited to the aforementioned solving means and other solving means which are not mentioned will be clearly understood by those skilled in the art from the present specification and the accompanying drawings.

### Advantageous Effects

According to an embodiment of the present disclosure, a LiDAR device in which a back-beam phenomenon is solved can be provided.

The effects of the present disclosure are not limited to the aforementioned effects and other effects which are not mentioned will be clearly understood by those skilled in the art from the present specification and the accompanying drawings.

### DESCRIPTION OF DRAWINGS

FIG. 1 is a diagram illustrating a LiDAR device according to an embodiment.

FIG. 2 is a diagram illustrating a LiDAR device according to an embodiment.

FIG. 3 is a diagram illustrating a laser emitting array and a laser detecting array included in a LiDAR device according to an embodiment.

FIGS. 4 and 5 are diagrams illustrating a LiDAR device according to an embodiment.

FIGS. 6 and 7 are diagrams illustrating a laser emitting module and a laser detecting module according to an embodiment.

FIGS. 8 and 9 are diagrams illustrating an emitting optic module and a detecting optic module according to an embodiment.

FIG. 10 is a diagram illustrating a problem occurring in a LiDAR device according to an embodiment.

FIG. 11 is a diagram illustrating a problem occurring in a LiDAR device according to an embodiment.

FIG. 12 is a diagram illustrating an incident angle of light and transmittance with respect to a window module according to an embodiment.

FIG. 13 is a diagram illustrating a LiDAR device according to an embodiment.

FIG. 14 is a diagram illustrating a LiDAR device according to an embodiment.

FIG. 15 is a diagram illustrating a LiDAR device according to an embodiment.

FIG. 16 is a diagram illustrating a LiDAR device according to an embodiment.

FIG. 17 is a diagram illustrating a LiDAR device according to an embodiment.

FIG. 18 is a diagram illustrating a LiDAR device according to an embodiment.

FIGS. 19A and 19B are diagrams illustrating an angle of a laser emitted from a LiDAR device and an angle of a laser incident on a window module according to an embodiment.

### DETAILED DESCRIPTION

Embodiments described in the present specification are for clearly describing the idea of the present disclosure to those skilled in the art to which the present disclosure belongs, so the present disclosure is not limited to the embodiments described in the present specification and the scope of the present disclosure should be construed as including modifications or variations that are within the idea of the present disclosure.

As the terms used in the present specification, general terms currently widely used are used considering functions in the present disclosure. However, the terms may vary according to the intentions of those skilled in the art, precedents, or the emergence of new technology. However, unlike this, when a particular term is used defined as having an optional meaning, the meaning of the term will be described. Thus, the terms used in the present specification should be construed based on the actual meanings of the terms and details throughout the present specification rather than simply the names of the terms.

The drawings accompanying the present specification are for easily describing the present disclosure, and the shapes shown in the drawings may be exaggerated to help the understanding of the present disclosure, so the present disclosure is not limited by the drawings.

When an element or layer described in the present specification is referred to as being on another element or layer, it may be directly on the other element or layer or an intervening layer or element may be present.

Throughout the present specification, the same reference numerals denote the same elements in principle.

Numbers (for example, first, second, etc.) used in the description of the present specification may be understood as identifiers for distinguishing one element from another.

The terms “module” and “part” that are used in the description of the present specification are used considering only the ease with which the present specification is written. The terms are not intended as having different special meanings or functions and thus may be used individually or interchangeably.

In the present specification, if it is decided that a detailed description of known configuration or function related to the present disclosure makes the subject matter of the present disclosure unclear, the detailed description is omitted.

According to an embodiment of the present disclosure,

According to an embodiment of the present disclosure, a LiDAR device may be provided comprising : a transmission module comprising a laser emitting array and a transmission optic, wherein the transmission optic comprises a first optical axis and a transmission entrance pupil; a reception module comprising a laser detecting array and a reception optic, wherein the reception optic comprises a second optical axis; a case configured to accommodate at least a portion of the transmission module and at least a portion of the reception module; and a window module configured to provide an internal space for accommodating the transmission optic and the reception optic when combined with the case; wherein the window module comprises a first optical window that allows light emitted from the transmission module to exit from the internal space, and a second optical window that allows light to be received by the reception module to enter the internal space, wherein a first laser emitting unit included in the laser emitting array is configured to emit a first laser, wherein the first laser emitting unit is disposed in a central region of the laser emitting array, wherein the first laser passes through a first region of the first optical window, wherein a second laser emitting unit included in the laser emitting array is configured to emit a second laser, wherein the second laser emitting unit is disposed at an edge of the laser emitting array, wherein a second region of the first optical window is curved, and wherein a radius of curvature of the first region is greater than a distance between the transmission entrance pupil and the first region.

wherein the second laser passes through the second region of the first optical window, and wherein a distance between the first optical axis and the second region is less than one half of a distance between the first optical axis and the second optical axis.

wherein all lasers emitted from the laser emitting array exit from the internal space without passing through the second optical window.

wherein the first laser passes through a third region of an outermost lens of the transmission optic, and wherein a distance between a virtual plane on which the laser emitting array is located and the third region is greater than a distance between the virtual plane and the second region of the first optical window.

wherein the second laser passes through a fourth region of the outermost lens of the transmission optic, and wherein a distance between the first region and the third region is different from a distance between the second region and the fourth region.

wherein the first optical window and the second optical window are physically formed integrally.

wherein a direction in which a laser output from the laser emitting array travels while passing through the first optical window is different from a direction in which the laser emitted from the laser emitting array travels while passing through the second optical window.

wherein the second laser emitting unit is disposed in a same row as the first laser emitting unit.

wherein the second laser emitting unit and the first laser emitting unit are configured to emit laser simultaneously.

wherein the first laser emitted from the first laser emitting unit is steered in a first direction through the transmission optic and exits from the internal space through the first optical window, and wherein, when the first laser is reflected from an object located in the first direction, the reflected first laser enters the internal space through the second optical window, is focused through the reception optic, and is detected by a first laser detecting unit.

wherein the second laser passes through the second region of the first optical window, and

wherein, when the second laser is incident on the second region of the first optical window, an angle between the second region and the second laser is smaller than an angle between the second laser irradiated to an outside of the LiDAR device and the first optical axis of the transmission optic.

wherein the transmission entrance pupil is defined as a position on a virtual plane perpendicular to the first optical axis, and wherein the virtual plane passing through a point at which the first optical axis intersects a virtual line extending backward along a traveling direction of a chief ray among light bundles constituting the second laser emitted from the second laser emitting unit after being steered through the transmission optics.

wherein the LiDAR device comprises an optic hood for providing a transmission internal space for accommodating at least a portion of the transmission optic and a reception internal space for accommodating at least a portion of the reception optic.

wherein the first region is a region which a chief ray among light bundles constituting the first laser emitted from the first laser emitting unit passes through.

wherein the first region is a region through which light bundles constituting the first laser emitted from the first laser emitting unit pass.

wherein a center of curvature defined by a curvature of the first region of the first optical window is located between the first region and the laser emitting array.

wherein a center of curvature defined by a curvature of the first region of the first optical window is located inside the transmission optic.

Hereinafter, a LiDAR device according to the present disclosure will be described.

However, the LiDAR device described in the present specification may be understood as a concept including various devices that measure a distance using a laser, and for example, may be understood as a concept including light detection and ranging (LiDAR) and a time-of-flight (TOF) sensor. However, there is no limitation thereto.

The LiDAR device is a device for detecting a distance to an object and a position of the object by using a laser. For example, the LiDAR device can emit a laser, and when the emitted laser is reflected from an object, the LiDAR device can receive the reflected laser to measure the distance between the object and the LiDAR device and the position of the object. Herein, the distance to and the position of the object may be represented through a coordinate system. For example, the distance to and the position of the object may be represented in a spherical coordinate system (r, θ, φ). However, there is no limitation thereto. These may be represented in a rectangular coordinate system (X, Y, Z) or a cylindrical coordinate system (r, θ, z).

In addition, herein, the object may mean at least one article. However, there is no limitation thereto, and the object may also mean a portion of an article for reflecting at least a portion of a laser emitted from the LiDAR device.

In addition, in order to measure a distance to an object, a LiDAR device according to an embodiment may use a laser that is emitted from the LiDAR device and reflected from the object.

For example, a LiDAR device according to an embodiment may use the time of flight (TOF) that it takes for a laser to be detected after emission, so as to measure a distance to an object.

As a more specific example, a LiDAR device according to an embodiment can measure a distance to an object by using the difference between a time value based on the time of emission when a laser is emitted and a time value based on the time of detection when the laser reflected from the object is detected.

Herein, the time value based on the time of emission of a laser may be acquired on the basis of a controller included in a LiDAR device according to an embodiment.

For example, the time value based on the time of emission of a laser may be acquired on the basis of a time point of generation of a trigger signal generated by a controller included in a LiDAR device according to an embodiment. However, there is no limitation thereto.

In addition, the time value based on the time of emission of a laser may be acquired on the basis of a laser emission part included in a LiDAR device according to an embodiment.

For example, the time value based on the time of emission of a laser may be acquired by detecting the operation of a laser emission part included in a LiDAR device according to an embodiment. However, there is no limitation thereto.

Herein, detection of the operation of the laser emission part may mean detection of a flow of current of the laser emission part or a change in an electric field. However, there is no limitation thereto.

In addition, the time value based on the time of emission of a laser may be acquired on the basis of a detector part included in a LiDAR device according to an embodiment.

For example, the time value based on the time of emission of a laser may be acquired on the basis of a time value at which a laser not reflected from the object is detected by a detector part included in a LiDAR device according to an embodiment. However, there is no limitation thereto.

Herein, a reference light path along which a laser emitted from the laser emission part is received by the detector part may be provided, but there is no limitation thereto.

In addition, the time value based on the time of detection of a laser reflected from the object and detected may be acquired on the basis of a detector part included in a LiDAR device according to an embodiment.

For example, the time value based on the time of detection of a laser reflected from the object and detected may be acquired on the basis of a time value at which a laser reflected from the object is detected by a detector part included in a LiDAR device according to an embodiment. However, there is no limitation thereto.

In addition to the time of flight, a LiDAR device according to an embodiment may use a triangulation method, an interferometry method, or phase shift measurement in order to measure a distance to an object. However, there is no limitation thereto.

A LiDAR device according to one embodiment may be installed at a vehicle. For example, the LiDAR device may be installed at a roof, a hood, a headlamp, or a bumper of a vehicle.

In addition, a plurality of LiDAR devices according to an embodiment may be installed at a vehicle. For example, when two LiDAR devices are installed on the roof of a vehicle, one of the LiDAR devices may be for observing ahead and the other may be for observing behind. However, there is no limitation thereto. In addition, for example, when two LiDAR devices are installed on the roof of a vehicle, one of the LiDAR devices may be for observing left and the other may be for observing right. However, there is no limitation thereto.

In addition, a LiDAR device according to an embodiment may be installed at a vehicle. For example, when the LiDAR device is installed inside a vehicle, the LiDAR device may be for recognizing a driver’s gestures during driving. However, there is no limitation thereto. In addition, for example, when the LiDAR device is installed inside or outside a vehicle, the LiDAR device may be for recognizing the driver’s face. However, there is no limitation thereto.

A LiDAR device according to an embodiment may be installed at an unmanned aerial vehicle. For example, the LiDAR device may be installed at an unmanned aerial vehicle system (UAV system), a drone, a remotely piloted vehicle (RPV), an unmanned aerial vehicle system (UAVs), an unmanned aircraft system (UAS), a remotely piloted air/aerial vehicle (RPAV), or a remotely piloted aircraft system (RPAS).

In addition, a plurality of LiDAR devices according to an embodiment may be installed at an unmanned aerial vehicle. For example, when two LiDAR devices are installed at an unmanned aerial vehicle, one of the LiDAR devices may be for observing ahead and the other may be for observing behind. However, there is no limitation thereto. In addition, for example, when two LiDAR devices are installed at an unmanned aerial vehicle, one of the LiDAR devices may be for observing left and the other may be for observing right. However, there is no limitation thereto.

A LiDAR device according to an embodiment may be installed at a robot. For example, the LiDAR device may be installed in a personal robot, a professional robot, a public service robot, other industrial robots, or a manufacturing robot.

In addition, a plurality of LiDAR devices according to an embodiment may be installed at a robot. For example, when two LiDAR devices are installed at a robot, one of the LiDAR devices may be for observing ahead and the other may be for observing behind. However, there is no limitation thereto. In addition, for example, when two LiDAR devices are installed at a robot, one of the LiDAR devices may be for observing left and the other may be for observing right. However, there is no limitation thereto.

In addition, a LiDAR device according to an embodiment may be installed at a robot. For example, when the LiDAR device is installed at a robot, the LiDAR device may be for recognizing a human’s face. However, there is no limitation thereto.

In addition, a LiDAR device according to an embodiment may be installed for industrial security. For example, the LiDAR device may be installed at a smart factory for industrial security.

In addition, a plurality of LiDAR devices according to an embodiment may be installed at a smart factory for industrial security. For example, when two LiDAR devices are installed at a smart factory, one of the LiDAR devices may be for observing ahead and the other may be for observing behind. However, there is no limitation thereto. In addition, for example, when two LiDAR devices are installed at a smart factory, one of the LiDAR devices may be for observing left and the other may be for observing right. However, there is no limitation thereto.

In addition, a LiDAR device according to an embodiment may be installed for industrial security. For example, when the LiDAR device is installed for industrial security, the LiDAR device may be for recognizing a human’s face. However, there is no limitation thereto.

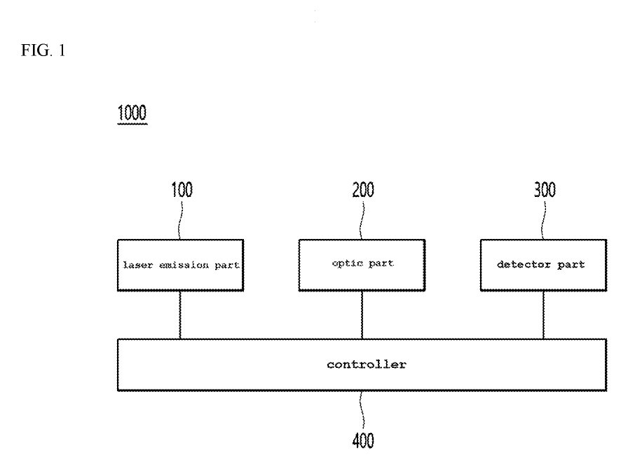

FIG. 1 is a diagram illustrating a LiDAR device according to an embodiment.

Referring to FIG. 1, a LiDAR device 1000 according to an embodiment may include a laser emission part 100.

Herein, the laser emission part 100 according to an embodiment may generate or emit a laser.

In addition, the laser emission part 100 according to an embodiment may include one or more laser emitting elements.

For example, the laser emission part 100 according to an embodiment may include a single laser emitting element or a plurality of laser emitting elements.

In addition, the laser emission part 100 according to an embodiment may be configured as an array in which a plurality of laser emitting elements are arranged in the form of an array. However, there is no limitation thereto.

For example, the laser emission part 100 according to an embodiment may be implemented as a vertical-cavity surface-emitting laser (VCSEL) array in which a plurality of VCSELs are arranged in the form of an array. However, there is no limitation thereto.

In addition, the laser emission part 100 according to an embodiment may include a laser emitting element such as a laser diode (LD), a solid-state laser, a high-power laser, a light emitting diode (LED), a vertical-cavity surface-emitting laser (VCSEL), or an external cavity diode laser (ECDL). However, there is no limitation thereto.

In addition, a wavelength of a laser emitted from the laser emission part 100 according to an embodiment may be positioned within a particular wavelength range.

For example, a wavelength of a laser emitted from the laser emission part 100 according to an embodiment may be positioned in a 905 nm band, a 940 nm band, or a 1550 nm band. However, there is no limitation thereto.

Herein, a wavelength band may mean a band within a particular range with respect to a center wavelength.

For example, the 905 nm band may mean a band within a range of a 10 nm difference with respect to 905 nm, the 940 nm band may mean a band within a range of a 10 nm difference with respect to 940 nm, and the 1550 nm band may mean a band within a range of a 10 nm difference with respect to 1550 nm. However, there is no limitation thereto.

In addition, a wavelength of a laser emitted from the laser emission part 100 according to an embodiment may be positioned within various wavelength ranges.

For example, a wavelength of a first laser emitted from a first laser emitting element included in the laser emission part 100 according to an embodiment may be positioned within a 905 nm band, and a wavelength of a second laser emitted from a second laser emitting element included in the laser emission part 100 according to an embodiment may be positioned within a 1550 nm band. However, there is no limitation thereto.

In addition, wavelengths of lasers emitted from the laser emission part 100 according to an embodiment may be positioned within a particular wavelength range, but may be different from each other.

For example, a wavelength of a first laser emitted from a first laser emitting element included in the laser emission part 100 according to an embodiment may be positioned within a 940 nm band and may be a wavelength of 939 nm, and a wavelength of a second laser emitted from a second laser emitting element included in the laser emission part 100 according to an embodiment may be positioned within the 940 nm band and may be a wavelength of 943 nm. However, there is no limitation thereto.

Referring back to FIG. 1, the LiDAR device 1000 according to an embodiment may include an optic part 200.

Herein, in order to describe the present disclosure, the optic part may be variously referred to as a steering part or a scanning part. However, there is no limitation thereto.

The optic part 200 according to an embodiment may function to change a flight path of a laser.

For example, the optic part 200 according to an embodiment may function to change a flight path of a laser emitted from the laser emission part 100, and when a laser emitted from the laser emission part 100 is reflected from an object, the optic part may function to change a flight path of the laser reflected from the object. However, there is no limitation thereto.

In addition, the optic part 200 according to an embodiment can function to change a flight path of a laser by reflecting the laser.

For example, the optic part 200 according to an embodiment may function to change a flight path by reflecting a laser emitted from the laser emission part 100, and when a laser emitted from the laser emission part 100 is reflected from an object, the optic part may function to change a flight path by reflecting the laser reflected from the object. However, there is no limitation thereto.

Herein, the optic part 200 according to an embodiment may include at least one optical means among various optical means for reflecting a laser.

For example, the optic part 200 according to an embodiment may comprise at least one optical means among optical means such as a mirror, a resonance scanner, a MEMS mirror, a voice coil motor (VCM), a polygonal mirror, a rotating mirror, and a Galvano mirror. However, there is no limitation thereto.

In addition, the optic part 200 according to an embodiment can change a flight path of a laser by refracting the laser.

For example, the optic part 200 according to an embodiment can function to change a flight path by refracting a laser emitted from the laser emission part 100, and when a laser emitted from the laser emission part 100 is reflected from an object, the optic part can function to change a flight path by refracting the laser reflected from the object. However, there is no limitation thereto.

Herein, the optic part 200 according to an embodiment may comprise at least one optical means among various optical means for refracting a laser.

For example, the optic part 200 according to an embodiment may include at least one optical means among optical means such as a lens, a prism, a microlens, a microfluidic lens, and a metasurface. However, there is no limitation thereto.

In addition, the optic part 200 according to an embodiment may change a flight path of a laser by changing a phase of the laser.

For example, the optic part 200 according to an embodiment can function to change a flight path by changing a phase of a laser emitted from the laser emission part 100, and when a laser emitted from the laser emission part 100 is reflected from an object, the optic part can function to change a flight path by changing a phase of the laser reflected from the object. However, there is no limitation thereto.

Herein, the optic part 200 according to an embodiment may comprise at least one optical means among various optical means for changing a phase of a laser.

For example, the optic part 200 according to an embodiment may include at least one optical means among optical means such as an optical phased array (OPA), a metalens, and a metasurface. However, there is no limitation thereto.

In addition, the optic part 200 according to an embodiment may include two or more optic parts.

For example, the optic part 200 according to an embodiment may include a transmitting optic unit for irradiating a scan region of the LiDAR device with a laser emitted from the laser emission unit 100 according to an embodiment, and a receiving optic unit for transferring a laser reflected from an object to a detector part 300. However, there is no limitation thereto.

In addition, for example, the optic part 200 according to an embodiment may comprise a first optic part for changing a flight path of a laser emitted from the laser emission part 100 according to an embodiment toward a direction of a first group, and a second optic part for changing a flight path of a laser emitted from the laser emission part 100 according to an embodiment toward a direction of a second group. However, there is no limitation thereto.

In addition to the examples described above, the optic part 200 according to an embodiment may be provided in a combination of various configurations to extend a scan region of the LiDAR device by using a laser emitted from the laser emission part 100 according to an embodiment and to transfer a laser reflected from an object to a detector part 300 according to an embodiment.

Referring back to FIG. 1, the LiDAR device 1000 according to an embodiment may comprise a detector part 300.

Herein, in order to describe the present disclosure, the detector part may be variously referred to as a light receiving unit, a receiver, or a sensor. However, there is no limitation thereto.

The detector part 300 according to an embodiment can function to detect a laser.

For example, the detector part 300 according to an embodiment can detect a laser reflected from an object positioned within a scan region of the LiDAR device 1000 according to an embodiment.

In addition, the detector part 300 according to an embodiment may be disposed to receive a laser, and can function to generate an electrical signal on the basis of the received laser.

For example, the detector part 300 according to an embodiment may be disposed to receive a laser reflected from an object positioned within a scan region of the LiDAR device 1000 according to an embodiment, and can generate an electrical signal on the basis of the laser.

Herein, the detector part 300 according to an embodiment may be disposed to receive, through at least one optical means, a laser reflected from an object positioned within a scan region of the LiDAR device 1000 according to an embodiment. The at least one optical means may be included in the above-described optic part, and may comprise an optical filter. However, there is no limitation thereto.

In addition, the detector part 300 according to an embodiment can generate detection information of a laser on the basis of a generated electrical signal.

For example, the detector part 300 according to an embodiment can generate detection information of a laser by comparing a predetermined threshold value with a rising edge, a falling edge, or a median value of the rising edge and the falling edge of a generated electrical signal. However, there is no limitation thereto.

In addition, for example, the detector part 300 according to an embodiment can generate histogram data corresponding to detection information of a laser on the basis of a generated electrical signal. However, there is no limitation thereto.

In addition, the detector part 300 according to an embodiment can determine a time point of detection of a laser on the basis of generated detection information of a laser.

For example, the detector part 300 according to an embodiment can determine a time point of detection of a laser on the basis of detection information of the laser generated on the basis of a rising edge of a generated electrical signal, or can determine a time point of detection of a laser on the basis of detection information of the laser generated on the basis of a falling edge of a generated electrical signal, or may determine a time point of detection of a laser on the basis of detection information of the laser generated on the basis of a rising edge of a generated electrical signal and detection information of the laser generated on the basis of a falling edge of the generated electrical signal. However, there is no limitation thereto.

In addition, for example, the detector part 300 according to an embodiment can determine a time point of detection of a laser on the basis of histogram data generated on the basis of a generated electrical signal. However, there is no limitation thereto.

As a more specific example, the detector part 300 according to an embodiment can determine a time point of detection of a laser on the basis of a peak of generated histogram data and determination of a rising edge and a falling edge based on a predetermined value. However, there is no limitation thereto.

Herein, the histogram data may be generated on the basis of an electrical signal generated from the detector part 300 according to an embodiment during at least one scan cycle.

In addition, the detector part 300 according to an embodiment may include at least one detector element among various detector elements.

For example, the detector part 300 according to an embodiment may comprise at least one detector element among detector elements such as a PN photodiode, a phototransistor, a PIN photodiode, an avalanche photodiode (APD), a single-photon avalanche diode (SPAD), a silicon photomultiplier (SiPM), a comparator, a complementary metal-oxide-semiconductor (CMOS), and a charge coupled device (CCD). However, there is no limitation thereto.

In addition, the detector part 300 according to an embodiment may include one or more detector elements.

For example, the detector part 300 according to an embodiment may comprise a single detector element or a plurality of detector elements.

In addition, the detector part 300 according to an embodiment may be configured as an array in which a plurality of detector elements are arranged in the form of an array. However, there is no limitation thereto.

For example, the detector part 300 according to an embodiment may be implemented as a single-photon avalanche diode (SPAD) array in which a plurality of SPADs are arranged in the form of an array. However, there is no limitation thereto.

Referring back to FIG. 1, the LiDAR device 1000 according to an embodiment may comprise a controller 400.

Herein, in order to describe the present disclosure, the controller may be variously referred to as a control unit. However, there is no limitation thereto.

The controller 400 according to an embodiment can control the operation of the laser emission part 100, the optic part 200, or the detector part 300.

In addition, the controller 400 according to an embodiment can control the operation of the laser emission part 100.

For example, the controller 400 can control a time point of emission of a laser emitted from the laser emission part 100. In addition, the controller 400 can control the power of a laser emitted from the laser emission part 100. In addition, the controller 400 can control the pulse width of a laser emitted from the laser emission part 100. In addition, the controller 400 can control the period of a laser emitted from the laser emission part 100. In addition, when the laser emission part 100 comprises a plurality of laser emitting elements, the controller 400 can control the laser emission part 100 such that some of the plurality of laser emitting elements operate.

In addition, the controller 400 according to an embodiment can control the operation of the optic part 200.

For example, the controller 400 can control the operating speed of the optic part 200. Specifically, when the optic part 200 includes a rotating mirror, the controller 400 can control the rotation speed of the rotating mirror. When the optic part 200 includes a MEMS mirror, the controller 400 can control the repetition period of the MEMS mirror. However, there is no limitation thereto.

In addition, for example, the controller 400 can control the degree of operation of the optic part 200. Specifically, when the optic part 200 includes a MEMS mirror, the controller 400 may control the angle of operation of the MEMS mirror. However, there is no limitation thereto.

In addition, the controller 400 according to an embodiment can control the operation of the detector part 300.

For example, the controller 400 can control the sensitivity of the detector part 300. Specifically, the controller 400 can control the sensitivity of the detector part 300 by adjusting a predetermined threshold value. However, there is no limitation thereto.

In addition, for example, the controller 400 can control the operation of the detector part 300. Specifically, the controller 400 can control the on/off operation of the detector part 300. When a plurality of sensor elements are included, the controller 400 can control the operation of the detector part 300 such that some of the sensor elements operate.

In addition, the controller 400 according to an embodiment can generate detection information of a laser on the basis of an electrical signal generated from the detector part 300.

For example, the controller 400 according to an embodiment can generate detection information of a laser by comparing a predetermined threshold value with a rising edge, a falling edge, or a median value of the rising edge and the falling edge of an electrical signal generated from the detector part 300. However, there is no limitation thereto.

In addition, for example, the controller 400 according to an embodiment can generate histogram data corresponding to detection information of a laser on the basis of an electrical signal generated from the detector part 300. However, there is no limitation thereto.

In addition, the controller 400 according to an embodiment may determine a time point of detection of a laser on the basis of detection information of a laser generated from the detector part 300.

For example, the controller 400 according to an embodiment can determine a time point of detection of a laser on the basis of detection information of the laser generated on the basis of a rising edge of an electrical signal generated from the detector part 300, or can determine a time point of detection of a laser on the basis of detection information of the laser generated on the basis of a falling edge of a generated electrical signal, or can determine a time point of detection of a laser on the basis of detection information of the laser generated on the basis of a rising edge of a generated electrical signal and detection information of the laser generated on the basis of a falling edge of the generated electrical signal. However, there is no limitation thereto.

In addition, for example, the controller 400 according to an embodiment can determine a time point of detection of a laser on the basis of histogram data generated on the basis of an electrical signal generated from the detector part 300. However, there is no limitation thereto.

As a more specific example, the controller 400 according to an embodiment can determine a time point of detection of a laser on the basis of a peak of histogram data generated from the detector part 300 and determination of a rising edge and a falling edge based on a predetermined value. However, there is no limitation thereto.

Herein, the histogram data may be generated on the basis of an electrical signal generated from the detector part 300 according to an embodiment during at least one scan cycle.

In addition, the controller 400 according to an embodiment can acquire information on a distance to an object on the basis of a determined time point of detection of a laser.

For example, the controller 400 according to an embodiment can acquire information on a distance to an object on the basis of a determined time point of emission of a laser and a determined time point of detection of the laser. However, there is no limitation thereto.

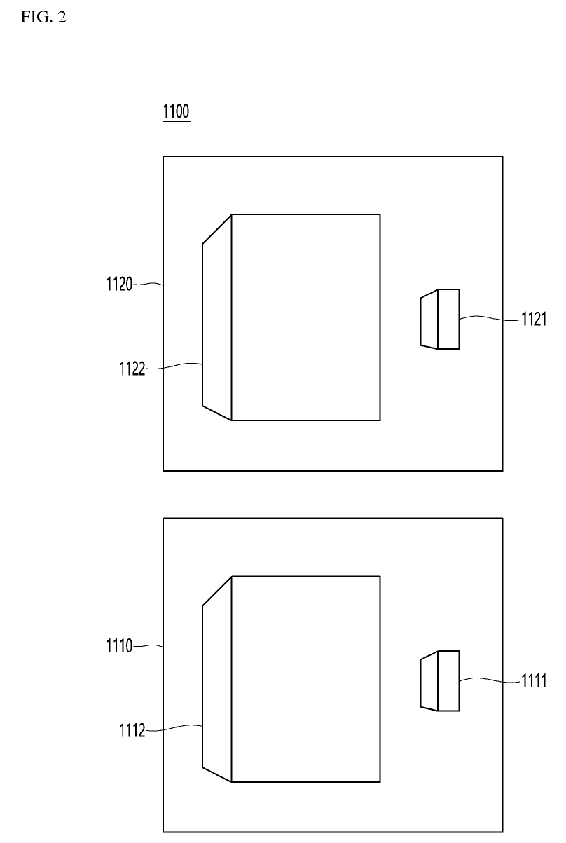

FIG. 2 is a diagram illustrating a LiDAR device according to an embodiment.

Referring to FIG. 2, a LiDAR device 1100 according to an embodiment may include a transmission module 1110 and a reception module 1120.

In addition, the transmission module 1110 may include a laser emitting array 1111 and a first lens assembly 1112. However, there is no limitation thereto.

Herein, the above-described details of the laser emission part may be applied to the laser emitting array 1111, so a redundant description will be omitted.

In addition, herein, for convenience, the first lens assembly 1112 may be referred to as a transmission lens assembly, a transmission optic, a transmission optic part, a transmission optic module, an emitting optic, an emitting optic part, or an emitting optic module. However, there is no limitation thereto.

In addition, the laser emitting array 1111 can emit at least one laser. For example, the laser emitting array 1111 can emit a plurality of lasers. However, there is no limitation thereto.

In addition, the laser emitting array 1111 can emit at least one laser at a first wavelength. For example, the laser emitting array 1111 can emit at least one laser at a wavelength of 940 nm, or can emit a plurality of lasers at a wavelength of 940 nm. However, there is no limitation thereto.

Herein, the first wavelength may be a wavelength range including an error range. For example, the first wavelength may mean a wavelength range from 935 nm to 945 nm, which is a wavelength of 940 nm with an error range of 5 nm. However, there is no limitation thereto.

In addition, the laser emitting array 1111 can emit at least one laser at the same time point. For example, the laser emitting array 1111 can emit at least one laser at the same time point, such as emitting a first laser at a first time point or emitting first and second lasers at a second time point.

In addition, the first lens assembly 1112 may include at least two lens layers. For example, the first lens assembly 1112 may include at least four lens layers. However, there is no limitation thereto.

In addition, the first lens assembly 1112 can collimate a laser emitted from the laser emitting array 1111. For example, the first lens assembly 1112 can change a divergence of a first laser by collimating the first laser emitted from the laser emitting array 1111. However, there is no limitation thereto.

In addition, the first lens assembly 1112 can steer a laser emitted from the laser emitting array 1111. For example, the first lens assembly 1112 can steer a first laser emitted from the laser emitting array 1111 in a first direction and can steer a second laser emitted from the laser emitting array 1111 in a second direction. However, there is no limitation thereto.

In addition, the first lens assembly 1112 can steer a plurality of lasers emitted from the laser emitting array 1111 such that the plurality of lasers are radiated at different angles in a range of (x) degrees to (y) degrees. For example, the first lens assembly 1112 can steer a first laser in a first direction such that the first laser emitted from the laser emitting array 1111 is radiated at an angle of (x) degrees, and may steer a second laser in a second direction such that the second laser emitted from the laser emitting array 1111 is radiated at an angle of (y) degrees. However, there is no limitation thereto.

In addition, the reception module 1120 may include a laser detecting array 1121 and a second lens assembly 1122. However, there is no limitation thereto.

Herein, the above-described details of the detector part may be applied to the laser detecting array 1121, so a redundant description will be omitted.

In addition, herein, for convenience, the second lens assembly 1122 may be referred to as a reception lens assembly, a reception optic, a reception optic part, a reception optic module, a receiving optic, a receiving optic part, or a receiving optic module. However, there is no limitation thereto.

In addition, the laser detecting array 1121 can detect at least one laser. For example, the laser detecting array 1121 can detect a plurality of lasers.

In addition, the laser detecting array 1121 may include a plurality of detectors. For example, the laser detecting array 1121 may include a first detector and a second detector. However, there is no limitation thereto.

In addition, a plurality of detectors included in the laser detecting array 1121 can receive different lasers, respectively. For example, a first detector included in the laser detecting array 1121 can receive a first laser received in a first direction and a second detector can receive a second laser received in a second direction. However, there is no limitation thereto.

In addition, the laser detecting array 1121 can detect at least a portion of a laser radiated from the transmission module 1110. For example, the laser detecting array 1121 can detect at least a portion of a first laser radiated from the transmission module 1110 and at least a portion of a second laser. However, there is no limitation thereto.

In addition, the second lens assembly 1122 can transfer a laser radiated from the transmission module 1110 to the laser detecting array 1121. For example, when a first laser radiated from the transmission module 1110 in a first direction is reflected from an object positioned in the first direction, the second lens assembly 1122 can transfer the first laser to the laser detecting array 1121. When a second laser radiated in a second direction is reflected from an object positioned in the second direction, the second lens assembly can transfer the second laser to the laser detecting array 1121. However, there is no limitation thereto.

In addition, the second lens assembly 1122 can distribute a laser radiated from the transmission module 1110 to at least two different detectors. For example, when a first laser radiated from the transmission module 1110 in a first direction is reflected from an object positioned in the first direction, the second lens assembly 1122 can distribute the first laser to a first detector included in the laser detecting array 1121. When a second laser radiated in a second direction is reflected from an object positioned in the second direction, the second lens assembly can distribute the second laser to a second detector included in the laser detecting array 1121. However, there is no limitation thereto.

In addition, the laser emitting array 1111 and the laser detecting array 1121 may be at least partially matched. For example, a first laser emitted from a first laser emitting element included in the laser emitting array 1111 may be detected by a first detector included in the laser detecting array 1121. When a second laser emitted from a second laser emitting element included in the laser emitting array 1111 may be detected by a second detector included in the laser detecting array 1121. However, there is no limitation thereto.

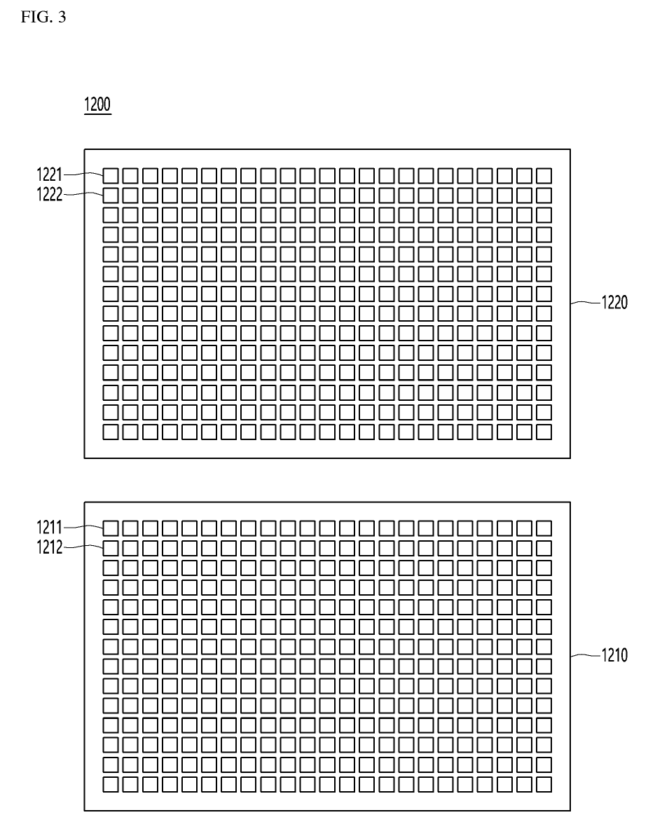

FIG. 3 is a diagram illustrating a laser emitting array and a laser detecting array included in a LiDAR device according to an embodiment.

Referring to FIG. 3, a LiDAR device 1200 according to an embodiment may include a laser emitting array 1210 and a laser detecting array 1220.

Herein, the above-described details may be applied to the laser emitting array 1210 and the laser detecting array 1220, so a redundant description will be omitted.

The laser emitting array 1210 may include a plurality of laser emitting units.

For example, the laser emitting array 1210 may include a first laser emitting unit 1211 and a second laser emitting unit 1212.

In addition, the laser emitting array 1210 may be an array in which a plurality of laser emitting units are arranged in the form of a 2D matrix.

For example, the laser emitting array 1210 may be an array in which a plurality of laser emitting units are arranged in the form of a 2D matrix having M rows and N columns. However, there is no limitation thereto.

In addition, each of the plurality of laser emitting units may include at least one laser emitting element.

For example, the first laser emitting unit 1211 included in the plurality of laser emitting units may be configured as one laser emitting element and the second laser emitting unit 1212 may be configured as one laser emitting element. However, there is no limitation thereto.

In addition, for example, the first laser emitting unit 1211 included in the plurality of laser emitting units may be configured as two or more laser emitting elements and the second laser emitting unit 1212 may be configured as two or more laser emitting elements. However, there is no limitation thereto.

In addition, lasers respectively emitted from the plurality of laser emitting units may be radiated in different directions.

For example, a first laser emitted from the first laser emitting unit 1211 included in the plurality of laser emitting units may be radiated in a first direction, and a second laser emitted from the second laser emitting unit 1212 may be radiated in a second direction. However, there is no limitation thereto.

In addition, lasers respectively emitted from the plurality of laser emitting units may not overlap with each other at a target position.

For example, the first laser emitted from the first laser emitting unit 1211 included in the plurality of laser emitting units and the second laser emitted from the second laser emitting unit 1212 may not overlap with each other at a distance of 100 m. However, there is no limitation thereto.

The laser detecting array 1220 may include a plurality of detecting units.

For example, the laser detecting array 1220 may include a first detecting unit 1221 and a second detecting unit 1222.

In addition, the laser detecting array 1220 may be an array in which a plurality of detecting units are arranged in the form of a 2D matrix.

For example, the laser detecting array 1220 may be an array in which a plurality of detecting units are arranged in the form of a 2D matrix having M rows and N columns. However, there is no limitation thereto.

In addition, each of the plurality of detecting units may comprise at least one laser detecting element.

For example, the first detecting unit 1221 included in the plurality of detecting units may be configured as one laser detecting element and the second detecting unit 1222 may be configured as one laser detecting element. However, there is no limitation thereto.

In addition, for example, the first detecting unit 1221 included in the plurality of detecting units may be configured as two or more laser detecting elements and the second detecting unit 1222 may be configured as two or more laser detecting elements. However, there is no limitation thereto.

In addition, the plurality of detecting units can respectively detect lasers radiated in different directions.

For example, the first detecting unit 1221 included in the plurality of laser emitting units can detect a first laser radiated in a first direction and the second detecting unit 1222 can detect a second laser radiated in a second direction. However, there is no limitation thereto.

In addition, each of the plurality of detecting units can detect a laser emitted from a laser emitting unit disposed to correspond thereto.

For example, the first detecting unit 1221 included in the plurality of detecting units can detect a first laser emitted from the first laser emitting unit 1211 disposed to correspond to the first detecting unit 1221, and the second detecting unit 1222 can detect a second laser emitted from the second laser emitting unit 1212 disposed to correspond to the second detecting unit 1222. However, there is no limitation thereto.

In addition, each of the plurality of detecting units can detect lasers emitted from at least two laser emitting units depending on a position of an object.

For example, when an object is positioned in a first distance range, the second detecting unit 1222 included in the plurality of detecting units can detect the second laser emitted from the second laser emitting unit 1212. When an object is positioned in a second distance range, the second detecting unit 1222 can detect the first laser emitted from the first laser emitting unit 1211. However, there is no limitation thereto.

In addition, at least one detecting value may be generated on the basis of a signal acquired from each of the plurality of detecting units.

Herein, the detecting value may include a depth value (distance value) and an intensity value. However, there is no limitation thereto.

In addition, coordinates of the detecting value may be determined on the basis of disposition of each of the plurality of detecting units.

For example, the first detecting unit 1221 included in the plurality of detecting units may be disposed at a position of (1,1) within the laser detecting array, and it may be determined that a first detecting value generated on the basis of a signal acquired from the first detecting unit 1221 has coordinates of (1,1). However, there is no limitation thereto.

In addition, for example, the second detecting unit 1222 included in the plurality of detecting units may be disposed at a position of (2,1) within the laser detecting array, and it may be determined that a second detecting value generated on the basis of a signal acquired from the second detecting unit 1222 has coordinates of (2,1). However, there is no limitation thereto.

In addition, the above-described examples merely describe cases in which coordinate values directly corresponding to a disposed position of each of the detecting units are calculated, but the present disclosure is not limited thereto and may include various rules for determining coordinates of the detecting value on the basis of disposition of each of the plurality of detecting units.

In addition, point data may be generated on the basis of the detecting value and the coordinates of the detecting value.

For example, first point data may be generated on the basis of a first detecting value generated on the basis of a signal acquired from the first detecting unit 1221 included in the plurality of detecting units and first coordinate values, which are coordinate values of the first detecting value. The first point data may include 3D position coordinate values and an intensity value. However, there is no limitation thereto.

In addition, for example, second point data may be generated on the basis of a second detecting value generated on the basis of a signal acquired from the second detecting unit 1222 included in the plurality of detecting units and second coordinate values, which are coordinate values of the second detecting value. The second point data may include 3D position coordinate values and an intensity value. However, there is no limitation thereto.

In addition, the laser emitting array 1210 and the laser detecting array 1220 may be arranged as arrays having the same dimension.

For example, the laser emitting array 1210 and the laser detecting array 1220 may be arranged as respective arrays in which both a plurality of laser emitting units and a plurality of detecting units have M rows and N columns. However, there is no limitation thereto.

In addition, the laser emitting array 1210 and the laser detecting array(1220) may be arranged as arrays having different dimensions.

For example, the laser emitting array 1210 may be arranged as an array in which a plurality of laser emitting units have M rows and N columns, and the laser detecting array 1220 may be arranged as an array in which a plurality of detecting units have M+3 rows and N columns. However, there is no limitation thereto.

In addition, the number of a plurality of laser emitting units included in the laser emitting array 1210 may be equal to the number of a plurality of detecting units included in the laser detecting array 1220.

For example, the laser emitting array 1210 may comprise M*N laser emitting units and the laser detecting array 1220 may comprise M*N detecting units. However, there is no limitation thereto.

In addition, the number of a plurality of laser emitting units included in the laser emitting array 1210 may be different from the number of a plurality of detecting units included in the laser detecting array 1220.

For example, the laser emitting array 1210 may comprise M*N laser emitting units and the laser detecting array 1220 may comprise (M+3)*N detecting units. However, there is no limitation thereto.

In addition, for example, the laser emitting array 1210 may comprise (M*N)/2 laser emitting units and the laser detecting array 1220 may comprise M*N detecting units. However, there is no limitation thereto.

In addition, for example, the laser emitting array 1210 may comprise (M*N)/2 laser emitting units and the laser detecting array 1220 may comprise (M+3)*N detecting units. However, there is no limitation thereto.

In addition, the number of laser emitting elements included in each of the plurality of laser emitting units included in the laser emitting array 1210 may be different from the number of laser detecting elements included in each of the plurality of laser detecting units included in the laser detecting array 1220.

For example, when one laser emitting element is included in the first laser emitting unit 1211, nine laser detecting elements may be included in the first detecting unit 1221. However, there is no limitation thereto.

In addition, for example, when one laser emitting element is included in the second laser emitting unit 1212, nine laser detecting elements may be included in the second detecting unit 1222. However, there is no limitation thereto.

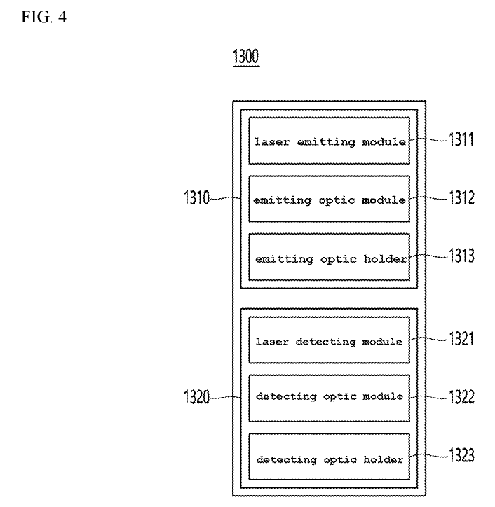

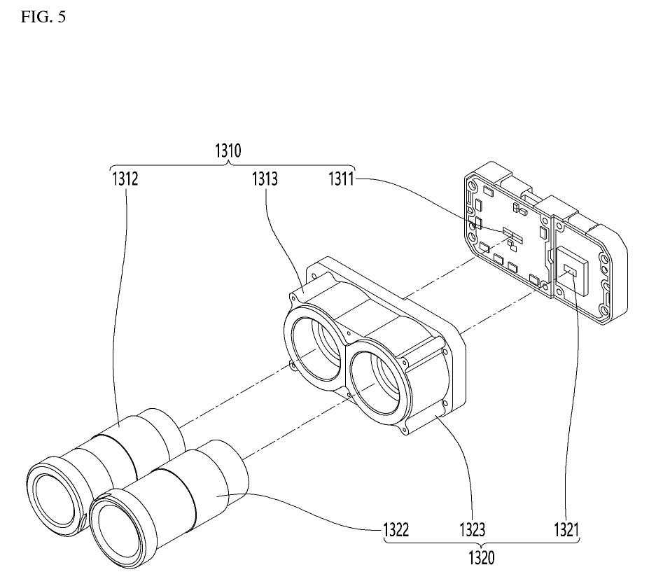

FIGS. 4 and 5 are diagrams illustrating a LiDAR device according to an embodiment.

Referring to FIGS. 4 and 5, a LiDAR device 1300 according to an embodiment may include a transmission module 1310 and a reception module 1320.

In addition, referring to FIGS. 4 and 5, the transmission module 1310 may further include a laser emitting module 1311, an emitting optic module 1312, and an emitting optic holder 1313.

Herein, the laser emitting module 1311 may include a laser emitting array. The above-described details may be applied to the laser emitting array, so a redundant description will be omitted.

In addition, the emitting optic module 1312 may include a lens assembly. The above-described details of the first lens assembly may be applied to the lens assembly, so a redundant description will be omitted.

In addition, the emitting optic holder 1313 may be positioned between the laser emitting module 1311 and the emitting optic module 1312.

For example, the emitting optic holder 1313 may be positioned between the laser emitting module 1311 and the emitting optic module 1312 to fix a relative positional relationship between the laser emitting module 1311 and the emitting optic module 1312. However, there is no limitation thereto.

In addition, the emitting optic holder 1313 may be formed to fix movement of the emitting optic module 1312.

For example, the emitting optic holder 1313 may be formed to comprise a hole into which at least a portion of the emitting optic module 1312 is inserted to restrict movement of the emitting optic module 1312. However, there is no limitation thereto.

In addition, referring to FIGS. 4 and 5, the reception module 1320 according to an embodiment may comprise a laser detecting module 1321, a detecting optic module 1322, and a detecting optic holder 1323.

Herein, the laser detecting module 1321 may comprise a laser detecting array. The above-described details may be applied to the laser detecting array, so a redundant description will be omitted.

In addition, the detecting optic module 1322 may comprise a lens assembly. The above-described details of the second lens assembly may be applied to the lens assembly, so a redundant description will be omitted.

In addition, the detecting optic holder 1323 may be positioned between the laser detecting module 1321 and the detecting optic module 1322.

For example, the detecting optic holder 1323 may be positioned between the laser detecting module 1321 and the detecting optic module 1322 to fix a relative positional relationship between the laser detecting module 1321 and the detecting optic module 1322. However, there is no limitation thereto.

In addition, the detecting optic holder 1323 may be formed to fix movement of the detecting optic module 1322.

For example, the detecting optic holder 1323 may be formed to comprise a hole into which at least a portion of the detecting optic module 1322 is inserted to restrict movement of the detecting optic module 1322. However, there is no limitation thereto.

In addition, the emitting optic holder 1313 and the detecting optic holder 1323 may be formed as an integrated object.

For example, the emitting optic holder 1313 and the detecting optic holder 1323 may be formed as an integrated object such that at least a portion of the emitting optic module 1312 and at least a portion of the detecting optic module 1322 are respectively inserted into two holes of one optic holder. However, there is no limitation thereto.

In addition, the emitting optic holder 1313 and the detecting optic holder 1323 may not be physically distinguished, and may conceptually mean to a first portion and a second portion of one optic holder. However, there is no limitation thereto.

In addition, FIG. 5 is a diagram illustrating an example of the LiDAR device of FIG. 4, and the description in FIG. 4 and the present disclosure are not limited by the shape shown in FIG. 5.

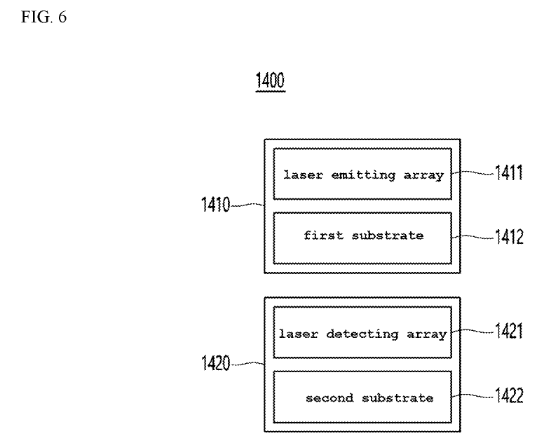

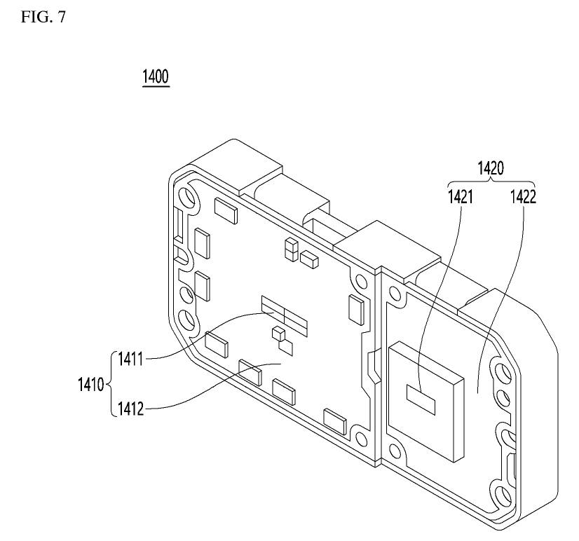

FIGS. 6 and 7 are diagrams illustrating a laser emitting module and a laser detecting module according to an embodiment.

Referring to FIGS. 6 and 7, a LiDAR device 1400 according to an embodiment may comprise a laser emitting module 1410 and a laser detecting module 1420.

In addition, referring to FIGS. 6 and 7, the laser emitting module 1410 according to an embodiment may include a laser emitting array 1411 and a first substrate 1412.

Herein, the above-described details may be applied to the laser emitting array 1411, so a redundant description will be omitted.

The laser emitting array 1411 according to an embodiment may be provided in the form of a chip in which a plurality of laser emitting units are arranged in the form of an array. However, there is no limitation thereto.

For example, the laser emitting array 1411 may be provided in the form of a laser emitting chip. However, there is no limitation thereto.

In addition, the laser emitting array 1411 may be positioned on the first substrate 1412. However, there is no limitation thereto.

In addition, the first substrate 1412 may comprise a laser emitting driver for controlling the operation of the laser emitting array 1411. However, there is no limitation thereto.

In addition, referring to FIGS. 6 and 7, the laser detecting module 1420 according to an embodiment may comprise a laser detecting array 1421 and a second substrate 1422.

Herein, the above-described details may be applied to the laser detecting array 1421, so a redundant description will be omitted.

The laser detecting array 1421 according to an embodiment may be provided in the form of a chip in which a plurality of laser detecting units are arranged in the form of an array. However, there is no limitation thereto.

For example, the laser detecting array 1421 may be provided in the form of a laser detecting chip. However, there is no limitation thereto.

In addition, the laser detecting array 1421 may be positioned on the second substrate 1422. However, there is no limitation thereto.

In addition, the second substrate 1422 may comprise a laser detecting driver for controlling the operation of the laser detecting array 1421. However, there is no limitation thereto.

In addition, the first substrate 1412 and the second substrate 1422 may be provided separately from each other as shown in FIG. 6. However, there is no limitation thereto, and the first substrate 1412 and the second substrate 1422 may be provided as a single substrate.

In addition, FIG. 7 is a diagram illustrating an example of the LiDAR device of FIG. 6, and the description in FIG. 6 and the present disclosure are not limited by the shape shown in FIG. 7.

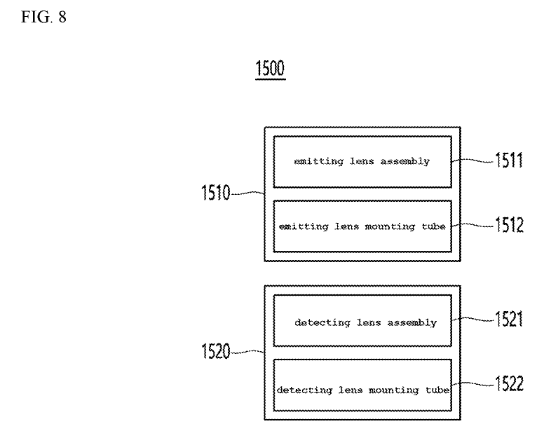

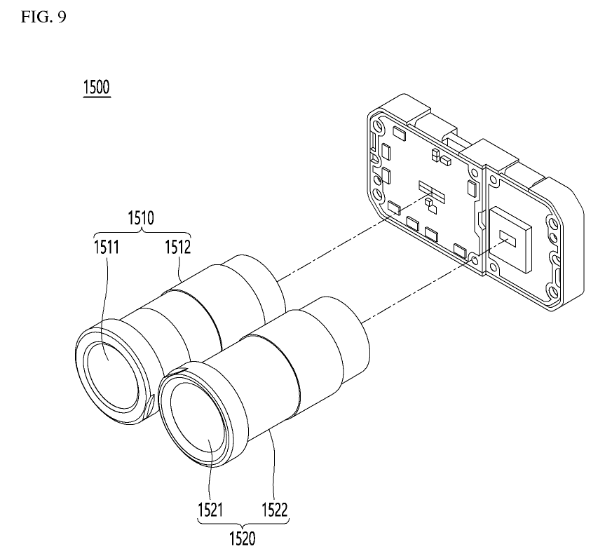

FIGS. 8 and 9 are diagrams illustrating an emitting optic module and a detecting optic module according to an embodiment.

Referring to FIGS. 8 and 9, a LiDAR device 1500 according to an embodiment may comprise an emitting optic module 1510 and a detecting optic module 1520.

In addition, referring to FIGS. 8 and 9, the emitting optic module 1510 according to an embodiment may comprise an emitting lens assembly 1511 and an emitting lens mounting tube 1512.

Herein, the above-described details may be applied to the emitting lens assembly 1511, so a redundant description will be omitted.

The emitting lens assembly 1511 according to an embodiment may be disposed within the emitting lens mounting tube 1512.

In addition, the emitting lens mounting tube 1512 may mean a barrel surrounding the emitting lens assembly 1511. However, there is no limitation thereto.

In addition, referring to FIGS. 8 and 9, the detecting optic module 1520 according to an embodiment may comprise a detecting lens assembly 1521 and a detecting lens mounting tube 1522.

Herein, the above-described details may be applied to the detecting lens assembly 1521, so a redundant description will be omitted.

The detecting lens assembly 1521 according to an embodiment may be disposed within the detecting lens mounting tube 1522.

In addition, the detecting lens mounting tube 1522 may mean a barrel surrounding the detecting lens assembly 1521. However, there is no limitation thereto.

In addition, referring to FIG. 9, the emitting optic module 1510 may be disposed so as to be aligned with the above-described laser emitting module.

Herein, the meaning that the emitting optic module 1510 is disposed so as to be aligned with the above-described laser emitting module may include both a meaning that the emitting optic module is disposed to physically have a preset relative positional relationship and a meaning that the emitting optic module is aligned to radiate a laser at an optically targeted angle. However, there is no limitation thereto.

In addition, referring to FIG. 9, the detecting optic module 1520 may be disposed so as to be aligned with the above-described laser detecting module.

Herein, the meaning that the detecting optic module 1520 is disposed so as to be aligned with the above-described laser detecting module may include both a meaning that the detecting optic module is disposed to physically have a preset relative positional relationship and a meaning that the detecting optic module is aligned to detect a laser received at an optically targeted angle. However, there is no limitation thereto.

In addition, FIG. 9 is a diagram illustrating an example of the LiDAR device of FIG. 8, and the description in FIG. 8 and the present disclosure are not limited by the shape shown in FIG. 9.

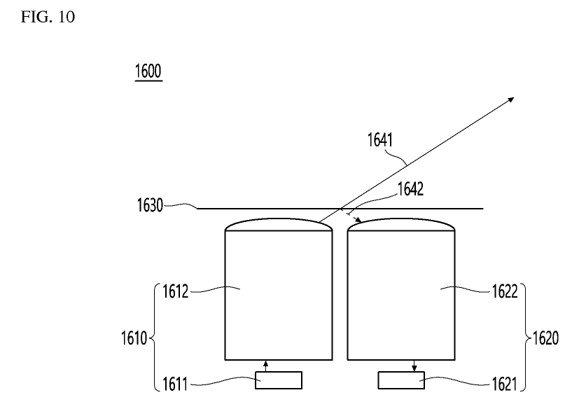

FIG. 10 is a diagram illustrating a problem occurring in a LiDAR device according to an embodiment.

Referring to FIG. 10, a LiDAR device 1600 according to an embodiment may comprise a transmission module 1610 and a reception module 1620. The transmission module 1610 may comprise a laser emitting array 1611 and a transmission optic 1612. The reception module 1620 may comprise a laser detecting array 1621 and a reception optic 1622.

Herein, the above-described details may be applied to the transmission module 1610 and the reception module 1620. The above-described details of the laser emitting array and the laser detecting array may be applied to the laser emitting array 1611 and the laser detecting array 1621. The above-described details of the transmission optic, the reception optic, the laser emitting optic module, and the laser detecting optic module may be applied to the transmission optic 1612 and the reception optic 1622, so a redundant description will be omitted.

In addition, referring to FIG. 10, the LiDAR device 1600 according to an embodiment may further include a window module 1630.

According to an embodiment, a laser 1641 emitted from the laser emitting array 1611 may be radiated in a first direction through the transmission optic 1612.

Herein, the laser 1641 emitted from the laser emitting array 1611 may pass through the window module 1630 of the LiDAR device 1600, and the laser 1641 may be at least partially reflected at a boundary of the window module 1630.

According to an embodiment, when the laser 1641 emitted from the laser emitting array 1611 is at least partially reflected at a boundary of the window module 1630, the reflected laser 1642 may be detected by the laser detecting array 1621 through the reception optic 1622.

In this case, erroneous-detection point data may be generated in response to detection of the reflected laser 1642 by the laser detecting array 1621, and accordingly, it may be incorrectly determined that an article is present where none actually exists.

In addition, in this case, at least some laser detecting elements included in the laser detecting array 1621 may be saturated in response to the reflected laser 1642. As a result, when an article is actually located at a close position, the article corresponding to that close position may not be detected.

As described above, a phenomenon in which erroneous detection or erroneous determination by the LiDAR device 1600 occurs in response to reflection of a laser from the window module 1630 included in the LiDAR device 1600 may be referred to as a back-beam phenomenon, and such a back-beam phenomenon may be a main cause of reducing the reliability of the LiDAR device 1600.

Therefore, it is necessary to provide a physical structure for preventing such a back-beam phenomenon.

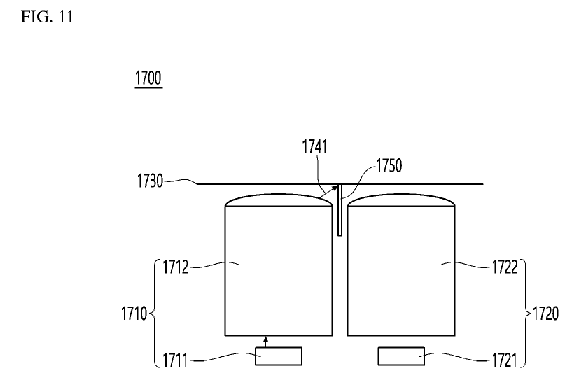

FIG. 11 is a diagram illustrating a problem occurring in a LiDAR device according to an embodiment.

Referring to FIG. 11, a LiDAR device 1700 according to an embodiment may include a transmission module 1710 and a reception module 1720. The transmission module 1710 may comprise a laser emitting array 1711 and a transmission optic 1712. The reception module 1720 may comprise a laser detecting array 1721 and a reception optic 1722.

Herein, the above-described details may be applied to the transmission module 1710 and the reception module 1720. The above-described details of the laser emitting array and the laser detecting array may be applied to the laser emitting array 1711 and the laser detecting array 1721. The above-described details of the transmission optic, the reception optic, the laser emitting optic module, and the laser detecting optic module may be applied to the transmission optic 1712 and the reception optic 1722, so a redundant description will be omitted.

In addition, referring to FIG. 11, the LiDAR device 1700 according to an embodiment may further comprise a window module 1730. The above-described details may be applied to the window module 1730, so a redundant description will be omitted.

In addition, referring to FIG. 11, the LiDAR device 1700 according to an embodiment may further comprise a back-beam prevention unit 1750 to prevent the back-beam phenomenon described above.

According to an embodiment, a laser 1741 emitted from the laser emitting array 1711 may be radiated in a first direction through the transmission optic 1712.

However, as shown in FIG. 11, the laser 1741 emitted from the laser emitting array 1711 may be blocked by the back-beam prevention unit 1750 and may not reach the window module 1730.

This may mean that a laser exiting the LiDAR device may be blocked by the back-beam prevention unit 1750 for preventing the back-beam phenomenon. As shown in FIG. 11, a steering angle of the laser 1741 emitted from the laser emitting array 1711 may need to be reduced to prevent the laser 1741 emitted from the laser emitting array 1711 from being blocked by the back-beam prevention unit 1750.

Accordingly, the field of view of the LiDAR device 1700 may be reduced by the back-beam prevention unit 1750 for preventing the back-beam phenomenon, and reduction in the field of view of the LiDAR device 1700 may mean degradation of performance of the LiDAR device 1700.

In addition, a distance between the transmission module 1710 and the reception module 1720 may need to be increased to prevent the laser 1741 emitted from the laser emitting array 1711 from being blocked by the back-beam prevention unit 1750.

When the distance between the transmission module 1710 and the reception module 1720 is increased, a blind region occurring at a short distance may increase depending on the distance between the transmission module 1710 and the reception module 1720, and the overall size of the LiDAR device 1700 may also increase.

Accordingly, a short-distance measurable region of the LiDAR device 1700 may be reduced by the back-beam prevention unit 1750 for preventing the back-beam phenomenon, and the size of the LiDAR device 1700 may increase, and degradation of overall performance of the LiDAR device 1700 may occur.

As described above with reference to FIGS. 10 and 11, although it is evident that the back-beam phenomenon occurring in the LiDAR device 1600, 1700 is a problem to be solved, degradation of performance of the LiDAR device 1600, 1700 may occur due to the back-beam prevention unit for solving the back-beam phenomenon.

Accordingly, there is a need for the development of a physical structure for preventing the back-beam phenomenon occurring in the LiDAR device 1600, 1700 while simultaneously minimizing degradation of performance of the LiDAR device 1600, 1700.

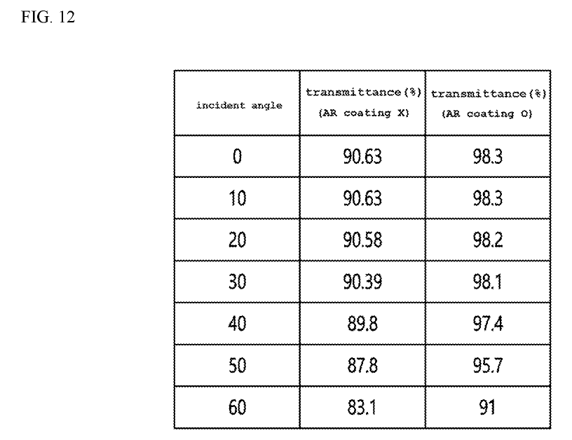

FIG. 12 is a diagram illustrating an incident angle of light and transmittance with respect to a window module according to an embodiment.

The window module described with reference to FIGS. 10 and 11 may be formed of a light-transmitting material capable of transmitting light, but transmittance may vary depending on an incident angle of light incident on the window module.

FIG. 12 is a diagram illustrating a table for describing transmittance that varies depending on an incident angle of light incident on the window module, and FIG. 12 shows transmittance of a window module without anti-reflection (AR) coating and for a window module with AR coating.

In the case of a LiDAR device including a window module described with reference to FIGS. 10 and 11, a laser emitted from a laser emitting array passes through a transmission optic and passes through the window module and is radiated toward the outside, and a laser reflected from an object at the outside passes through the window module and passes through a reception optic and reaches a laser detecting array.

Herein, a laser radiated at an angle of 0 degrees through the transmission optic is incident on the window module at an angle of 0 degrees and passes through the window module and is radiated toward the outside, and a laser reflected from an object at the outside is incident on the window module at an angle of 0 degrees and passes through the window module and passes through the reception optic and reaches the laser detecting array.

In addition, herein, a laser radiated at an angle of 60 degrees through the transmission optic is incident on the window module at an angle of 60 degrees and passes through the window module and is radiated toward the outside, and a laser reflected from an object at the outside is incident on the window module at an angle of 60 degrees and passes through the window module and passes through the reception optic and reaches the laser detecting array.

Hereinafter, based on the foregoing, a problem of the window module described above with reference to FIGS. 10 and 11 will be described.

Even if the window module according to an embodiment is formed of a light-transmitting material, this does not mean that 100 % of light is transmitted, and transmittance may vary depending on the material.

In addition, anti-reflection (AR) coating may be performed to increase light transmittance.

However, even if AR coating is performed, this does not mean that light transmittance is 100 %. As shown in the table of FIG. 12, light transmittance may decrease as the incident angle of light incident on the window module increases.

Accordingly, in a case of manufacturing a LiDAR device for securing a 120-degree field of view, a laser radiated to have an angle of 60 degrees with respect to the optical axis of the transmission optic is required, and the laser is incident on the window module at an angle of 60 degrees.

In addition, a laser radiated to have an angle of 60 degrees with respect to the optical axis of the transmission optic is reflected from an object and is incident on the LiDAR device as collimated light having an angle of 60 degrees with respect to the optical axis of the reception optic, so the reflected laser is incident on the window module at angle of 60 degrees.

That is, in the case of the window module without AR coating, only 81.1 % of photons of a laser radiated to have an angle of 60 degrees with respect to the optical axis of the transmission optic may pass through the window module when the laser exits the LiDAR device, and only 81.1 % of photons may pass through the window module when the laser enters the LiDAR device.

Accordingly, in the case of the window module without AR coating, even if all photons of a laser radiated to have an angle of 60 degrees with respect to the optical axis of the transmission optic are reflected from an object and directed toward the LiDAR device, only 65.77 % of photons may reach the laser detecting module.

In addition, in the case of the window module with AR coating, even if all photons of a laser radiated to have an angle of 60 degrees with respect to the optical axis of the transmission optic are reflected from an object and directed toward the LiDAR device, only 82.8 % of photons may reach the laser detecting module.

As described above, the LiDAR device may be a device for obtaining a distance value to an object by radiating a laser and detecting a laser reflected from the object. As the number of photons acquired by the LiDAR device decreases, a maximum measurement distance measurable by the LiDAR device may decrease.

That is, due to the window module described above with reference to FIGS. 10 and 11, the maximum measurement distance measurable by the LiDAR device may decrease, directly leading to degradation of performance of the LiDAR device.

Accordingly, the above-described problem may also need to be solved.

Hereinafter, a LiDAR device according to various embodiments capable of solving the problems described above with reference to FIGS. 10 to 12 will be described.

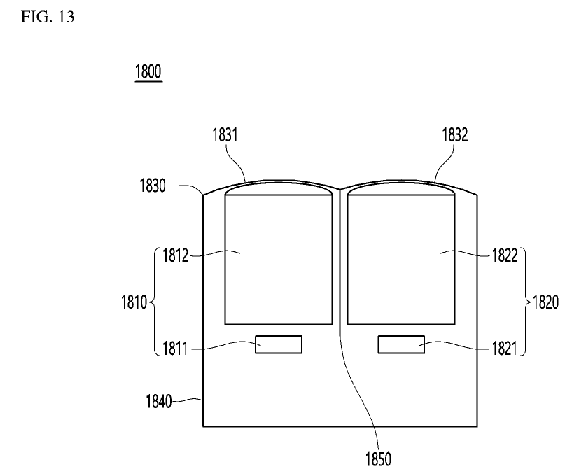

FIG. 13 is a diagram illustrating a LiDAR device according to an embodiment.

Referring to FIG. 13, a LiDAR device 1800 according to an embodiment may comprise a transmission module 1810 and a reception module 1820. The transmission module 1810 may comprise a laser emitting array 1811 and a transmission optic 1812. The reception module 1820 may comprise a laser detecting array 1821 and a reception optic 1822.

Herein, the above-described details may be applied to the transmission module 1810 and the reception module 1820. The above-described details of the laser emitting array and the laser detecting array may be applied to the laser emitting array 1811 and the laser detecting array 1821. The above-described details of the transmission optic, the reception optic, the laser emitting optic module, and the laser detecting optic module may be applied to the transmission optic 1812 and the reception optic 1822, so a redundant description will be omitted.

In addition, referring to FIG. 13, the LiDAR device 1800 according to an embodiment may further comprise a case 1840.

The case 1840 according to an embodiment may function to accommodate at least a portion of the transmission module 1810 and the reception module 1820.

For example, the case 1840 according to an embodiment may function to accommodate at least a portion of the transmission optic 1812 included in the transmission module 1810 and at least a portion of the reception optic 1822 included in the reception module 1820.

In addition, for example, the case 1840 according to an embodiment may function to accommodate at least a portion of the laser emitting array 1811 included in the transmission module 1810 and at least a portion of the laser detecting array 1821 included in the reception module 1820.

In addition, referring to FIG. 13, the LiDAR device 1800 according to an embodiment may further comprise a window module 1830.

The window module 1830 according to an embodiment may function to provide an internal space for accommodating at least a portion of the transmission module 1810 and the reception module 1820 by being combined with the case 1840.

For example, the window module 1830 according to an embodiment may function to provide an internal space for accommodate at least a portion of the transmission optic 1812 and the reception optic 1822 by being combined with the case 1840.

In addition, for example, the window module 1830 according to an embodiment may function to provide an internal space for accommodating at least a portion of the laser emitting array 1811 and the laser detecting array 1821 by being combined with the case 1840.

Herein, the internal space according to an embodiment may be provided so as to be physically isolated from an external space, which may be for waterproofing/dustproofing of the LiDAR device. However, there is no limitation thereto.

In addition, the window module 1830 according to an embodiment may comprise a first optical window 1831 that allows light emitted from the transmission module 1810 to exit the internal space, and a second optical window 1832 that allows light to be received by the reception module 1820 to enter the internal space.

For example, the window module 1830 according to an embodiment may include the first optical window 1831 that allows a laser to exit the internal space, the laser being emitted from the laser emitting array 1811 included in the transmission module 1810 and steered by the transmission optic 1812.

In addition, for example, the window module 1830 according to an embodiment may include the second optical window 1832 that allows a laser to enter the internal space, the laser being focused by the reception optic 1822 included in the reception module 1820 and to be detected by laser detecting array 1821.

Herein, the first optical window 1831 and the second optical window 1832 may be formed of a light-transmitting material.

In addition, herein, at least a portion of the first optical window 1831 and the second optical window 1832 may be formed to have a curvature.

In addition, the first optical window 1831 and the second optical window 1832 may be formed as a physically integrated object.

In addition, referring to FIG. 13, the LiDAR device 1800 according to an embodiment may further include a separation part 1850 for separating the transmission module 1810 and the reception module 1820.

The separation part 1850 according to an embodiment may be positioned between the transmission module 1810 and the reception module 1820.

For example, the separation part 1850 according to an embodiment may be positioned between the transmission optic 1812 included in the transmission module 1810 and the reception optic 1822 included in the reception module 1820.

In addition, the separation part 1850 according to an embodiment may be provided in the shape of a lens hood that includes a transmission hood part for accommodating at least a portion of the transmission module 1810 and a reception hood part for accommodating at least a portion of the reception module 1820.

For example, the separation part 1850 according to an embodiment may be provided in the shape of a lens hood in which the transmission hood part for accommodating the transmission optic 1812 included in the transmission module 1810 and the reception hood part for accommodating the reception optic 1822 included in the reception module 1820 are formed as an integrated object, wherein the space for accommodating the transmission optic 1812 and the space for accommodating the reception optic 1822 are formed to be separated from each other.

According to an embodiment, all lasers emitted from the transmission module 1810 may exit the internal space without passing through the second optical window.

For example, according to an embodiment, both a first laser and a second laser may exit the internal space by passing through the first optical window, and neither the first laser nor the second laser may exit the internal space by passing through the second optical window, wherein the first laser is emitted from a first laser emitting unit included in the laser emitting array 1811 and disposed in a central region of the laser emitting array 1811 and the second laser is emitted from a second laser emitting unit disposed in an edge region of the laser emitting array 1811.

Hereinafter, a more detailed design of the LiDAR device 1800 according to an embodiment will be described.

In addition, hereinafter, for convenience of description, the above-described reference numerals will be used throughout the following description.

However, this is merely for convenience of description, and the following describes various embodiments of a LiDAR device. It is clarified that a LiDAR device according to an embodiment of the present application may not only incorporate all of the various features described below, but may also incorporate at least a portion of the various features described below.

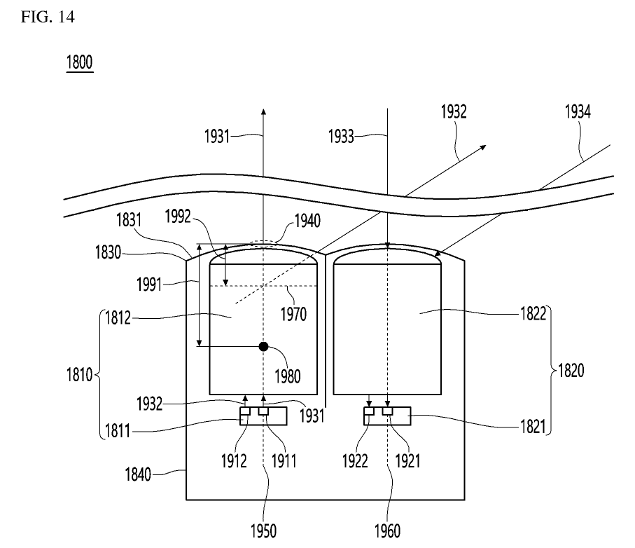

FIG. 14 is a diagram illustrating a LiDAR device according to an embodiment.

Referring to FIG. 14, a LiDAR device 1800 according to an embodiment may comprise a transmission module 1810, a reception module 1820, a window module 1830, and a case 1840. The transmission module 1810 may comprise a laser emitting array 1811 and a transmission optic 1812. The reception module 1820 may comprise a laser detecting array 1821 and a reception optic 1822. The window module 1830 may comprise a first optical window 1831 and a second optical window 1832.

Herein, the details described with reference to FIG. 13 may be applied to the above-described configurations, so a redundant description will be omitted.

Referring back to FIG. 14, a laser emitting array 1811 according to an embodiment may comprise a plurality of laser emitting units.

For example, the laser emitting array 1811 according to an embodiment may comprise a first laser emitting unit 1911 and a second laser emitting unit 1912.

Herein, the first laser emitting unit 1911 according to an embodiment may be disposed in a central region of the laser emitting array 1811 and can function to emit a first laser 1931.

In addition, herein, the second laser emitting unit 1912 according to an embodiment may be disposed in an edge region of the laser emitting array 1811 and can function to emit a second laser 1932.

In addition, the first laser emitting unit 1911 and the second laser emitting unit 1912 according to an embodiment may be disposed in the same row.

For example, the first laser emitting unit 1911 according to an embodiment may be disposed in a central region of a central row of the laser emitting array 1811, and the second laser emitting unit 1912 may be disposed in an edge region of a central row of the laser emitting array 1811. However, there is no limitation thereto.

In addition, the first laser emitting unit 1911 and the second laser emitting unit 1912 according to an embodiment may operate simultaneously.

For example, the laser emitting array 1811 according to an embodiment may be designed such that laser emitting units disposed on a row-by-row basis operate simultaneously, and the first laser emitting unit 1911 and the second laser emitting unit 1912 disposed in the same row may operate simultaneously to emit the first laser 1931 and the second laser 1932 simultaneously. However, there is no limitation thereto.

In addition, the second laser emitting unit 1912 according to an embodiment may be disposed closer to the reception module 1820 than the first laser emitting unit 1911.

That is, the second laser emitting unit 1912 according to an embodiment may be a laser emitting unit disposed in an edge region close to the reception module 1920.

In addition, according to an embodiment, the first laser 1931 emitted from the first laser emitting unit 1911 may be radiated in a first direction through the transmission optic 1812, and the first laser may be reflected from an object positioned in the first direction.

Herein, the first laser 1933 reflected from the object positioned in the first direction may reach the laser detecting array 1821 through the reception optic 1822.

In addition, according to an embodiment, the second laser 1932 emitted from the second laser emitting unit 1912 may be radiated in a second direction through the transmission optic 1812, and the second laser may be reflected from an object positioned in the second direction.

Herein, the second laser 1934 reflected from the object positioned in the second direction may reach the laser detecting array 1821 through the reception optic 1822.

Referring back to FIG. 14, the laser detecting array 1821 according to an embodiment may comprise a plurality of laser detecting units.

For example, the laser detecting array 1821 according to an embodiment may comprise a first laser detecting unit 1921 and a second laser detecting unit 1922.

Herein, the first laser detecting unit 1921 according to an embodiment may be disposed in a central region of the laser detecting array 1821 and may be optically connected to the first laser emitting unit 1911.

In addition, herein, the second laser detecting unit 1922 according to an embodiment may be disposed in an edge region of the laser detecting array 1821 and may be optically connected to the second laser emitting unit 1912.

Herein, optical connection between any one laser detecting unit and any one laser emitting unit may mean that they are mutually aligned such that the laser detecting unit functions to detect a laser emitted from the laser emitting unit.

For example, optical connection between the first laser detecting unit 1921 and the first laser emitting unit 1911 may mean that they are mutually aligned such that when the first laser 1931 emitted from the first laser emitting unit 1911 and radiated in a first direction through the transmission optic 1812 is reflected from an object positioned in the first direction, the first laser detecting unit 1921 functions to detect the reflected first laser 1933.

In addition, for example, optical connection between the second laser detecting unit 1922 and the second laser emitting unit 1912 may mean that they are mutually aligned such that when the second laser 1932 emitted from the second laser emitting unit 1912 and radiated in a second direction through the transmission optic 1812 is reflected from an object positioned in the second direction, the second laser detecting unit 1922 functions to detect the reflected second laser 1934.

Referring back to FIG. 14, the transmission optic 1812 according to an embodiment may have a first optical axis 1950, the reception optic 1822 according to an embodiment may have a second optical axis 1960, and respective optical axes of the transmission optic 1812 and the reception optic 1822 may be understood as a concept commonly understood as an optical axis by those skilled in the art.

In addition, the transmission optic 1812 according to an embodiment may comprise a transmission entrance pupil 1970.

Herein, the transmission entrance pupil 1970 may be defined as a virtual plane perpendicular to the first optical axis 1950, and the virtual plane passes through a point at which the first optical axis 1950 of the transmission optic 1812 intersects a virtual line extending backward along a traveling direction in which a chief ray of the second laser 1932 emitted from the second laser emitting unit 1912 exits after being steered by the transmission optic 1812.

Herein, the chief ray of the second laser 1932 may mean a light ray passing through the first optical axis 1950 of the transmission optic 1812 within the transmission optic 1812 among light bundles constituting the second laser 1932. However, there is no limitation thereto.

However, the above-described definition of the transmission entrance pupil 1970 is provided merely for convenience of description. However, there is no limitation thereto. The above-described definition of the transmission entrance pupil 1970 may be defined as a concept commonly understood as an entrance pupil of the transmission optic 1812 by those skilled in the art.

Referring back to FIG. 14, the first laser 1931 emitted from the first laser emitting unit 1911 according to an embodiment may be steered through the transmission optic 1812, and may pass through a first region 1940 of the first optical window 1831 to exit the internal space.

Herein, the first region 1940 of the first optical window 1831 may mean a region through which light bundles constituting the first laser 1931 pass, and may mean a region through which a chief ray among the light bundles constituting the first laser 1931 passes. However, there is no limitation thereto. The first region may be understood as a region of the first optical window 1831 through which the first laser 1931 passes.

In addition, the first region 1940 of the first optical window 1831 according to an embodiment may be formed to have a curvature.

For example, the first region 1940 of the first optical window 1831 according to an embodiment may be formed to have a first curvature.

Herein, the first region 1940 of the first optical window 1831 may include an inner surface and an outer surface. When the inner surface and the outer surface are provided to have different curvatures, the curvature of the first region 1940 of the first optical window 1831 may be specified as a curvature of either the inner surface or the outer surface. However, hereinafter, for convenience of description, the curvature of the inner surface or the outer surface of the first region 1940 of the first optical window 1831 will be described as the curvature of the first region 1940 of the first optical window 1831.

In addition, as the first region 1940 of the first optical window 1831 according to an embodiment is formed to have a curvature, a radius of curvature of the first region 1940 may be defined.

For example, as the first region 1940 of the first optical window 1831 according to an embodiment is formed to have the first curvature, the radius of curvature of the first region 1940 may be a first distance 1991.

In addition, the radius of curvature of the first region 1940 of the first optical window 1831 according to an embodiment may be defined by a center of curvature.

For example, the radius of curvature of the first region 1940 of the first optical window 1831 according to an embodiment may be the first distance 1991 which is a distance from a center 1980 of curvature for the curvature of the first region 1940 to the first region 1940.

Referring back to FIG. 14, the curvature of the first region 1940 of the first optical window 1831 according to an embodiment may be provided such that the radius of curvature of the first region 1940 of the first optical window 1831 is greater than a distance between the transmission entrance pupil 1970 and the first region 1940.

For example, when the distance between the first region 1940 and the transmission entrance pupil 1970 according to an embodiment is a second distance 1992, the first region 1940 is provided to have the first curvature. The curvature of the first region 1940 may be formed such that the first distance 1991, which is a length of a first radius of curvature defined by the first curvature, is greater than the second distance 1992.

In addition, the curvature of the first region 1940 of the first optical window 1831 according to an embodiment may be provided such that the radius of curvature of the first region 1940 of the first optical window 1831 is smaller than the distance between the first region 1940 and the laser emitting array 1811.

For example, when the distance between the first region 1940 and the laser emitting array 1811 according to an embodiment is a third distance, the first region 1940 is provided to have the first curvature. The curvature of the first region 1940 may be formed such that the first distance 1991, which is a length of the first radius of curvature defined by the first curvature, is smaller than the third distance.

In addition, unlike what is shown in FIG. 14, the curvature of the first region 1940 of the first optical window 1831 according to an embodiment may be provided such that the radius of curvature of the first region 1940 of the first optical window 1831 is greater than the distance between the first region 1940 and the laser emitting array 1811.

For example, when the distance between the first region 1940 and the laser emitting array 1811 according to an embodiment is the third distance, the first region 1940 is provided to have the first curvature. The curvature of the first region 1940 may be formed such that the first distance 1991, which is a length of the first radius of curvature defined by the first curvature, is greater than the third distance.

In addition, the curvature of the first region 1940 of the first optical window 1831 according to an embodiment may be formed such that the center 1980 of curvature defined by the curvature of the first region 1940 is positioned between the transmission entrance pupil 1970 and the laser emitting array 1811.

In addition, unlike what is shown in FIG. 14, the curvature of the first region 1940 of the first optical window 1831 according to an embodiment may be formed such that the center 1980 of curvature defined by the curvature of the first region 1940 is positioned on a plane on which the laser emitting array 1811 is positioned.

In addition, unlike what is shown in FIG. 14, the curvature of the first region 1940 of the first optical window 1831 according to an embodiment may be formed such that the center 1980 of curvature defined by the curvature of the first region 1940 is positioned further from the first region 1940 than the plane on which the laser emitting array 1811 is positioned.

In addition, according to the best embodiment of the present application, the curvature of the first region 1940 of the first optical window 1831 may be formed such that the radius of curvature defined by the curvature of the first region 1940 is greater than the second distance 1992, which is the distance between the first region 1940 and the transmission entrance pupil 1970, and is smaller than the third distance, which is the distance between the first region 1940 and the laser emitting array 1811, and the center 1980 of curvature defined by the curvature of the first region 1940 is positioned between the transmission entrance pupil 1970 and the laser emitting array 1811.

In addition, the above description of the curvature of the first region 1940 of the first optical window 1831 may be satisfied for both the curvature of the inner surface and the curvature of the outer surface of the first region 1940 of the first optical window 1831.

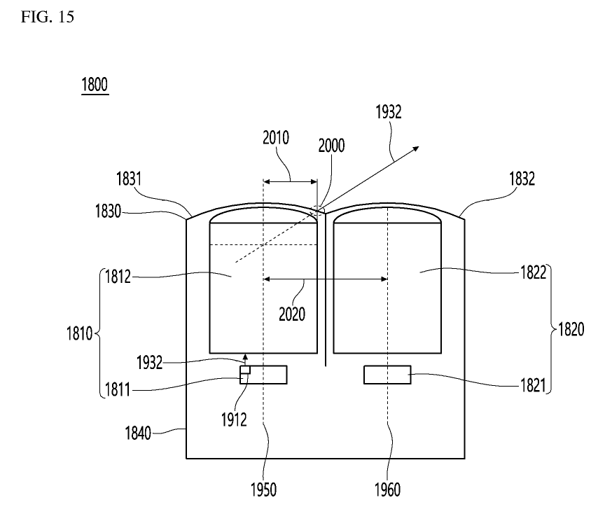

FIG. 15 is a diagram illustrating a LiDAR device according to an embodiment.

Referring to FIG. 15, a LiDAR device 1800 according to an embodiment may comprise a transmission module 1810, a reception module 1820, a window module 1830, and a case 1840. The transmission module 1810 may comprise a laser emitting array 1811 and a transmission optic 1812. The reception module 1820 may comprise a laser detecting array 1821 and a reception optic 1822. The window module 1830 may comprise a first optical window 1831 and a second optical window 1832.

Herein, the details described with reference to FIGS. 13 and 14 may be applied to the above-described configurations, so a redundant description will be omitted.

In addition, referring to FIG. 15, the transmission optic 1812 according to an embodiment may have a first optical axis 1950 and the reception optic 1822 may have a second optical axis 1960. The above-described details may be applied thereto, so a redundant description will be omitted.

In addition, referring to FIG. 15, the laser emitting array 1811 according to an embodiment may comprise a second laser emitting unit 1912. The above-described details may be applied thereto, so a redundant description will be omitted.

Referring back to FIG. 15, the second laser 1932 emitted from the second laser emitting unit 1912 according to an embodiment may be steered through the transmission optic 1812, and may pass through a second region 2000 of the first optical window 1831 to exit the above-described internal space.

Herein, the second region 2000 of the first optical window 1831 may mean region through which light bundles constituting the second laser 1932 pass, and may mean a region through which a chief ray among the light bundles constituting the second laser 1932 passes. However, there is no limitation thereto. The second region may be understood as a region of the first optical window 1831 through which the second laser 1932 passes.

In addition, the second region 2000 of the first optical window 1831 according to an embodiment may be formed to have a curvature.

For example, the second region 2000 of the first optical window 1831 according to an embodiment may be formed to have a second curvature.

Herein, the curvature of the second region 2000 of the first optical window 1831 may be formed to be identical to the curvature of the first region 1940 of the first optical window 1831 described above. However, there is no limitation thereto.

In addition, herein, the above-described details of the curvature of the first region 1940 of the first optical window 1831 may be applied to the curvature of the second region 2000 of the first optical window 1831, and regarding the above-described details of the curvature of the first region 1940 of the first optical window 1831, concepts understood by substituting the curvature of the first region 1940 of the first optical window 1831 with the curvature of the second region 2000 may be applied, so a redundant description will be omitted.

Referring back to FIG. 14, a distance between the second region 2000 of the first optical window 1831 and the first optical axis 1950 of the transmission optic 1812 according to an embodiment may be smaller than half of a distance between the first optical axis 1950 of the transmission optic 1812 and the second optical axis 1960 of the reception optic 1822.

For example, when the distance between the second region 2000 of the first optical window 1831 and the first optical axis 1950 of the transmission optic 1812 according to an embodiment is a fourth distance 2010 and the distance between the first optical axis 1950 of the transmission optic 1812 and the second optical axis 1960 of the reception optic 1822 is a fifth distance 2020, the fourth distance 2010 may be smaller than half of the fifth distance 2020.

In the LiDAR device 1800 including the transmission optic 1812 and the reception optic 1822, this may be a condition for all lasers emitted from the laser emitting array 1811 to pass through the first optical window 1831 and exit the internal space without passing through the second optical window 1832.

Referring back to FIG. 14, the distance between the second region 2000 of the first optical window 1831 and the first optical axis 1950 of the transmission optic 1812 according to an embodiment may be smaller than half of a distance between the center of the laser emitting array 1811 and the center of the laser detecting array 1821.

For example, when the distance between the second region 2000 of the first optical window 1831 and the first optical axis 1950 of the transmission optic 1812 according to an embodiment is the fourth distance 2010 and the distance between the center of the laser emitting array 1811 and the center of the laser detecting array 1821 is a sixth distance, the fourth distance 2010 may be smaller than half of the sixth distance.

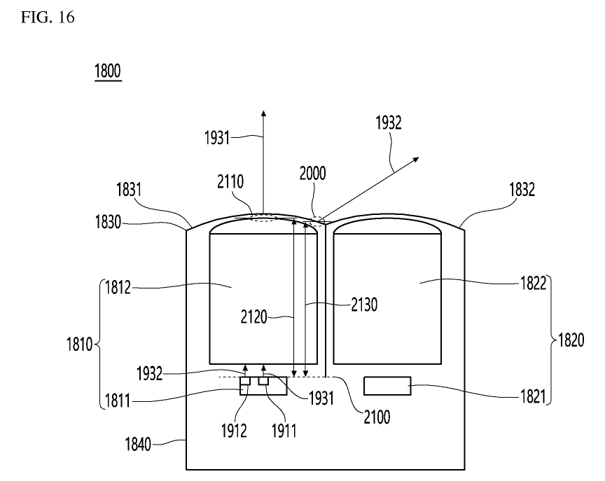

FIG. 16 is a diagram illustrating a LiDAR device according to an embodiment.

Referring to FIG. 16, a LiDAR device 1800 according to an embodiment may comprise a transmission module 1810, a reception module 1820, a window module 1830, and a case 1840. The transmission module 1810 may comprise a laser emitting array 1811 and a transmission optic 1812. The reception module 1820 may comprise a laser detecting array 1821 and a reception optic 1822. The window module 1830 may comprise a first optical window 1831 and a second optical window 1832.

Herein, the details described with reference to FIGS. 13, 14, and 15 may be applied to the above-described configurations, so a redundant description will be omitted.

In addition, referring to FIG. 16, the laser emitting array 1811 according to an embodiment may comprise a first laser emitting unit 1911 and a second laser emitting unit 1912. The first laser emitting unit 1911 can function to emit a first laser 1931. The second laser emitting unit 1912 can function to emit a second laser 1932. The above-described details may be applied to the above-described configurations, so a redundant description will be omitted.

Referring back to FIG. 16, the first laser 1931 emitted from the first laser emitting unit 1911 according to an embodiment may be steered through the transmission optic 1812, and may pass through a third region 2110 of an outermost lens of the transmission optic 1812, and may pass through the first optical window 1831 to exit the above-described internal space.

Herein, the third region 2110 of the outermost lens of the transmission optic 1812 may mean a region through which light bundles constituting the first laser 1931 pass, and may mean a region through which a chief ray among the light bundles constituting the first laser 1931 passes. However, there is no limitation thereto. The third region may be understood as a region of the outermost lens of the transmission optic 1812 through which the first laser 1931 passes.

In addition, the second laser 1932 emitted from the second laser emitting unit 1912 according to an embodiment may be steered through the transmission optic 1812, and may pass through a second region 2000 of the first optical window 1831 to exit the above-described internal space. The above-described details may be applied to the second region 2000, so a redundant description will be omitted.

Referring back to FIG. 16, a virtual plane 2100 on which the laser emitting array 1811 according to an embodiment is positioned may be defined.

Herein, the virtual plane 2100 on which the laser emitting array 1811 according to an embodiment is positioned may mean a plane formed by virtually extending the plane on which the laser emitting array 1811 is positioned. However, there is no limitation thereto.

Referring back to FIG. 16, the first optical window 1831 according to an embodiment may be designed such that there is a particular relationship between a distance from the virtual plane 2100 to the third region 2110 of the outermost lens of the transmission optic 1812 and the distance from the virtual plane 2100 to the second region 2000 of the first optical window 1831.

For example, the first optical window 1831 according to an embodiment may be designed such that a seventh distance 2120, which is the distance from the virtual plane 2100 to the third region 2110 of the outermost lens of the transmission optic 1812, is greater than an eighth distance 2130, which is the distance from the virtual plane 2100 to the second region 2000 of the first optical window 1831.

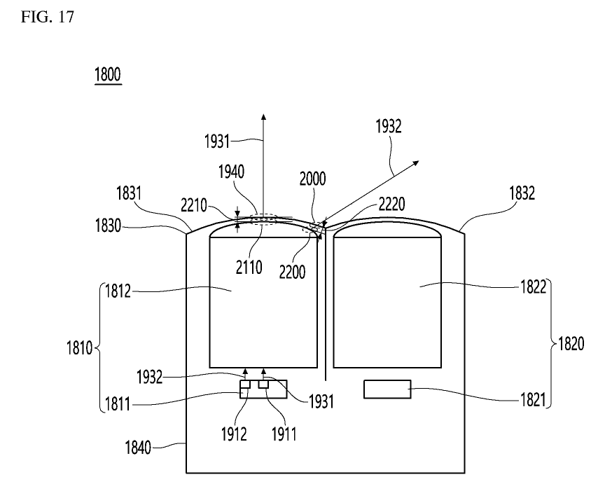

FIG. 17 is a diagram illustrating a LiDAR device according to an embodiment.

Referring to FIG. 17, a LiDAR device 1800 according to an embodiment may comprise a transmission module 1810, a reception module 1820, a window module 1830, and a case 1840. The transmission module 1810 may comprise a laser emitting array 1811 and a transmission optic 1812. The reception module 1820 may comprise a laser detecting array 1821 and a reception optic 1822. The window module 1830 may comprise a first optical window 1831 and a second optical window 1832.

Herein, the details described with reference to FIGS. 13, 14, 15, and 16 may be applied to the above-described configurations, so a redundant description will be omitted.

In addition, referring to FIG. 17, the laser emitting array 1811 according to an embodiment may comprise a first laser emitting unit 1911 and a second laser emitting unit 1912. The first laser emitting unit 1911 can function to emit a first laser 1931. The second laser emitting unit 1912 can function to emit a second laser 1932. The above-described details may be applied to the above-described configurations, so a redundant description will be omitted.

Referring back to FIG. 17, the first laser 1931 emitted from the first laser emitting unit 1911 according to an embodiment may be steered through the transmission optic 1812, and may pass through the first region 1940 of the first optical window 1831 to exit the above-described internal space. The above-described details may be applied to the first region 1940, so a redundant description will be omitted.

In addition, the first laser 1931 emitted from the first laser emitting unit 1911 according to an embodiment may be steered through the transmission optic 1812, and may pass through a third region 2110 of an outermost lens of the transmission optic 1812, and may pass through the first optical window 1831 to exit the above-described internal space. The above-described details may be applied to the third region 2110, so a redundant description will be omitted.

In addition, the second laser 1932 emitted from the second laser emitting unit 1912 according to an embodiment may be steered through the transmission optic 1812, and may pass through a second region 2000 of the first optical window 1831 to exit the above-described internal space. The above-described details may be applied to the second region 2000, so a redundant description will be omitted.

In addition, the second laser 1932 emitted from the second laser emitting unit 1912 according to an embodiment may be steered through the transmission optic 1812, and pass through a fourth region 2200 of an outermost lens of the transmission optic 1812, and may pass through the first optical window 1831 to exit the above-described internal space.

Herein, the fourth region 2200 of the outermost lens of the transmission optic 1812 may mean a region through which light bundles constituting the second laser 1932 pass, and may mean a region through which a chief ray among the light bundles constituting the second laser 1932 passes. However, there is no limitation thereto. The fourth region may be understood as a region of the outermost lens of the transmission optic 1812 through which the second laser 1932 passes.

Referring back to FIG. 17, the first optical window 1831 according to an embodiment may be designed such that there is a particular relationship among the first region 1940 and the second region 2000 of the first optical window 1831 and the third region 2110 and the fourth region 2200 of the outermost lens of the transmission optic 1812.

For example, the first optical window 1831 according to an embodiment may be designed such that a distance between the first region 1940 of the first optical window 1831 and the third region 2110 of the outermost lens of the transmission optic 1812 is different from a distance between the second region 2000 of the first optical window 1831 and the fourth region 2200 of the outermost lens of the transmission optic 1812.

In addition, for example, the first optical window 1831 according to an embodiment may be designed such that the distance between the first region 1940 of the first optical window 1831 and the third region 2110 of the outermost lens of the transmission optic 1812 is equal to the distance between the second region 2000 of the first optical window 1831 and the fourth region 2200 of the outermost lens of the transmission optic 1812.

In addition, for example, the first optical window 1831 according to an embodiment may be designed such that the distance between the first region 1940 of the first optical window 1831 and the third region 2110 of the outermost lens of the transmission optic 1812 is smaller than the distance between the second region 2000 of the first optical window 1831 and the fourth region 2200 of the outermost lens of the transmission optic 1812.

In addition, for example, the first optical window 1831 according to an embodiment may be designed such that the distance between the first region 1940 of the first optical window 1831 and the third region 2110 of the outermost lens of the transmission optic 1812 is greater than the distance between the second region 2000 of the first optical window 1831 and the fourth region 2200 of the outermost lens of the transmission optic 1812.

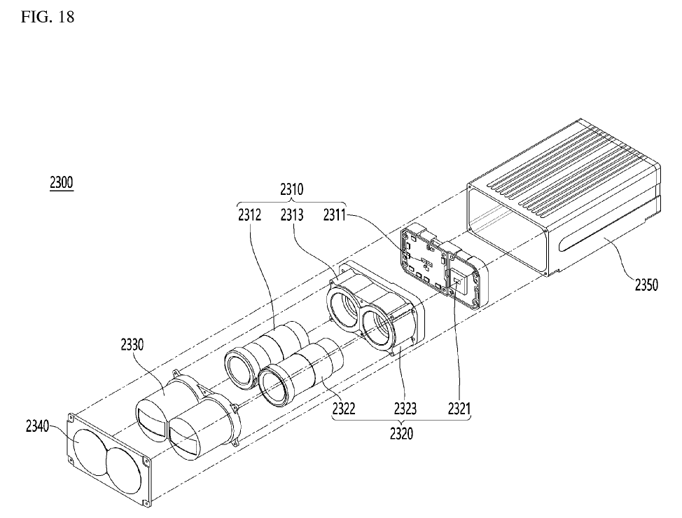

FIG. 18 is a diagram illustrating a LiDAR device according to an embodiment.

Referring to FIG. 18, a LiDAR device 2300 according to an embodiment may comprise a transmission module 2310, a reception module 2320, an optic hood 2330, a window module 2340, and a case 2350.

Herein, the transmission module 2310 may comprise a laser emitting module 2311, an emitting optic module 2312, and an emitting optic holder 2313. The above-described details may be applied thereto, so a redundant description will be omitted.

In addition, herein, the reception module 2320 may comprise a laser detecting module 2321, a detecting optic module 2322, and a detecting optic holder 2323. The above-described details may be applied thereto, so a redundant description will be omitted.

The optic hood 2330 according to an embodiment may be provided to be combined with the emitting optic holder 2313 and the detecting optic holder 2323 so as to form a transmission internal space and a reception internal space for accommodating at least a portion of the emitting optic module 2312 and the detecting optic module 2322.

In addition, the optic hood 2330 according to an embodiment may comprise at least one optical window that allows a laser emitted from the transmission module 2310 to exit the transmission internal space.

For example, the optic hood 2330 according to an embodiment may include a hole for passing therethrough a laser that is emitted from the laser emitting module 2311 and steered by the emitting optic module 2312. However, there is no limitation thereto.

In addition, for example, the optic hood 2330 according to an embodiment may include a light-transmitting material for transmitting therethrough a laser that is emitted from the laser emitting module 2311 and steered by the emitting optic module 2312. However, there is no limitation thereto.

In addition, the optic hood 2330 according to an embodiment may comprise at least one optical window that allows a laser to be detected by the reception module 2320 to enter the reception internal space.

For example, the optic hood 2330 according to an embodiment may include a hole for passing therethrough a laser that is focused by the detecting optic module 2322 and to be detected by the laser detecting module 2321. However, there is no limitation thereto.

In addition, for example, the optic hood 2330 according to an embodiment may include a light-transmitting material for transmitting therethrough a laser that is focused by the detecting optic module 2322 and to be detected by the laser detecting module 2321. However, there is no limitation thereto.

In addition, the optic hood 2330 according to an embodiment may be formed such that the transmission internal space and the reception internal space are separated from each other.

In addition, the optic hood 2330 according to an embodiment may be a configuration corresponding to the separation part 1850 described with reference to FIG. 13.

In addition, the window module 2340 according to an embodiment may be combined with the case 2350 according to an embodiment to form an internal space for accommodating at least a portion of the transmission module 2310 and the reception module 2320. The above-described details may be applied to the window module 2340 and the case 2350, so a redundant description will be omitted.

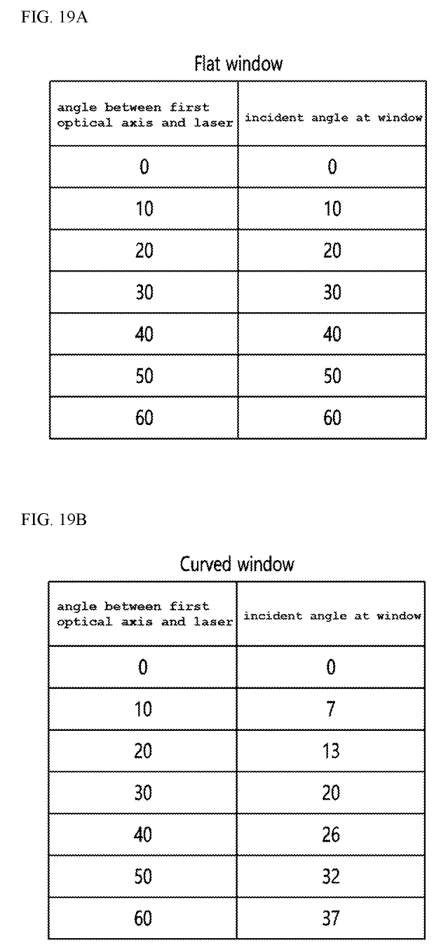

FIGS. 19A and 19B are diagrams illustrating an angle of a laser emitted from a LiDAR device and an angle of a laser incident on a window module according to an embodiment.

More specifically, FIG. 19A is a table showing an incident angle on the flat window module depending on an angle between the first optical axis of the transmission optic and a laser for the flat window module described with reference to FIGS. 10 and 11, and FIG. 19B is a table showing an incident angle on the curved window module depending on an angle between the first optical axis of the transmission optic and a laser for the curved window module described with reference to FIGS. 13 to 18.

Referring to FIGS. 19A and 19B, it can be seen that according to the design of the curved window module according to various embodiments of the present application, the incident angle incident on the window module is significantly reduced compared to the flat window module. Referring to the transmittance of the window module according to the incident angle described with reference to FIG. 12, it can be seen that the LiDAR device including the curved window module according to various embodiments of the present application has increased laser transmission/reception efficiency compared to the LiDAR device including the flat window module.

For a more detailed description, taking as an example in which a laser that forms an angle of 60 degrees between the first optical axis and the laser,

in the case of the flat window, the laser forming an angle of 60 degrees between the first optical axis and the laser may be incident on the window at an angle of 60 degrees. Accordingly, the transmittance of the window for the laser forming an angle of 60 degrees between the first optical axis and the laser may be i) 83.1 % without AR coating, and ii) 91 % with AR coating. (see FIG. 12)

In addition, in the case of the curved window, the laser forming an angle of 60 degrees between the first optical axis and the laser may be incident on the window at an angle of 37 degrees. Accordingly, the transmittance of the window for the laser forming an angle of 60 degrees between the first optical axis and the laser may be i) transmittance between 89.8 % and 90.39 % without AR coating, and ii) transmittance between 97.4 % and 98.1 % with AR coating.

That is, it can be understood that the LiDAR device including the curved window module according to various embodiments of the present application has increased laser transmission/reception efficiency compared to the LiDAR device including the flat window module.

Referring to the descriptions provided above, it is clear that by employing the window module according to various embodiments of the present disclosure, a LiDAR device can be provided which physically prevents a back-beam phenomenon that may occur in a fixed LiDAR device, without degrading the minimum detection distance performance and the maximum detection distance performance of the LiDAR device.

Methods according to the embodiments may be embodied as program instructions executable by various computer means and may be recorded on a computer-readable recording medium. The computer-readable recording medium may include program instructions, data files, data structures, and the like separately or in combinations. The program instructions to be recorded on the computer-readable recording medium may be specially designed and configured for the embodiments may be well-known to and be usable by those skilled in the art of computer software. Examples of the computer-readable recording medium include magnetic recording media such as hard disks, floppy disks and magnetic tapes; optical data storage media such as CD-ROMs or DVD-ROMs; magneto-optical media such as floptical disks; and hardware devices, such as read-only memory (ROM), random-access memory (RAM), and flash memory, which are particularly structured to store and implement the program instructions. Examples of the program instructions include not only a mechanical language code formatted by a compiler but also a high level language code that may be implemented by a computer using an interpreter, and the like. The hardware devices may be configured to be operated by one or more software modules or vice versa to conduct the operation according to the embodiments.

Although the embodiments have been described with reference to the limited embodiments and drawings, it will be understood by those skilled in the art that various modifications and variations may be made from the description. For example, suitable results may be achieved if the described techniques are performed in an order different from the described method, and/or the elements of the above-described system, structure, device, and circuit are coupled or combined in a form different from the described method, or replaced or substituted by other elements or equivalents.

Therefore, other implementations, other embodiments, and equivalents to the claims are also within the scope of the following claims.

Mode for Invention

As described above, in the best mode for carrying out the invention, related matters have been described.

What is claimed is:

1. A LiDAR device, comprising:
a transmission module comprising a laser emitting array and a transmission optic,
wherein the transmission optic comprises a first optical axis and a transmission entrance pupil;
a reception module comprising a laser detecting array and a reception optic,
wherein the reception optic comprises a second optical axis;
a case configured to accommodate at least a portion of the transmission module and at least a portion of the reception module; and
a window module configured to provide an internal space for accommodating the transmission optic and the reception optic when combined with the case;
wherein the window module comprises a first optical window that allows light emitted from the transmission module to exit from the internal space, and a second optical window that allows light to be received by the reception module to enter the internal space,
wherein a first laser emitting unit included in the laser emitting array is configured to emit a first laser,
wherein the first laser emitting unit is disposed in a central region of the laser emitting array,
wherein the first laser emitted from the first laser emitting unit is steered in a first direction through the transmission optic and exits from the internal space through a first region of the first optical window,
wherein a second laser emitting unit included in the laser emitting array is configured to emit a second laser,
wherein the second laser emitting unit is disposed at an edge of the laser emitting array,
wherein the second laser emitted from the second laser emitting unit is steered in a second direction through the transmission optic and exits from the internal space through a second region of the first optical window,
wherein the first optical window is configured to have a firstcurvature,
wherein the second optical window is configured to have a second curvature, and
wherein a center of the first curvature is different from a center of the second curvature.

2. The LiDAR device of claim 1,
wherein the first region of the first optical window is curved,
wherein a radius of curvature of the first region is greater than a distance between the transmission entrance pupil and the first region and
wherein a distance between the first optical axis and the second region is less than one half of a distance between the first optical axis and the second optical axis.

3. The LiDAR device of claim 1,
wherein all lasers emitted from the laser emitting array exit from the internal space without passing through the second optical window.

4. The LiDAR device of claim 1,
wherein the first laser passes through a third region of an outermost lens of the transmission optic, and
wherein a distance between a virtual plane on which the laser emitting array is located and the third region is greater than a distance between the virtual plane and the second region of the first optical window.

5. The LiDAR device of claim 4,
wherein the second laser passes through a fourth region of the outermost lens of the transmission optic, and
wherein a distance between the first region and the third region is different from a distance between the second region and the fourth region.

6. The LiDAR device of claim 1,
wherein the first optical window and the second optical window are physically formed integrally.

7. The LiDAR device of claim 1,
wherein a direction in which the laser output from the laser emitting array travels while passing through the first optical window is different from a direction in which the laser emitted from the laser emitting array travels while passing through the second optical window.

8. The LiDAR device of claim 1,
wherein the second laser emitting unit is disposed in a same row as the first laser emitting unit.

9. The LiDAR device of claim 8,
wherein the second laser emitting unit and the first laser emitting unit are configured to emit laser simultaneously.

10. The LiDAR device of claim 1,
wherein, when the first laser is reflected from an object located in the first direction, the reflected first laser enters the internal space through the second optical window, is focused through the reception optic, and is detected by a first laser detecting unit included in the laser detecting array.

11. The LiDAR device of claim 1,
wherein the second laser passes through the second region of the first optical window, and
wherein, when the second laser is incident on the second region of the first optical window, an angle between the second region and the second laser is smaller than an angle between the second laser irradiated to an outside of the LiDAR device and the first optical axis of the transmission optic.

12. The LiDAR device of claim 1,
wherein the transmission entrance pupil is defined as a position on a virtual plane perpendicular to the first optical axis, the virtual plane passing through a point at which the first optical axis intersects a virtual line extending backward along a traveling direction of a chief ray among light bundles constituting the second laser emitted from the second laser emitting unit after being steered through the transmission optics.

13. The LiDAR device of claim 1,
wherein the LiDAR device comprises an optic hood for providing a transmission internal space for accommodating at least a portion of the transmission optic and a reception internal space for accommodating at least a portion of the reception optic.

14. The LiDAR device of claim 1,
wherein the first region is a region which a chief ray among light bundles constituting the first laser emitted from the first laser emitting unit passes through.

15. The LiDAR device of claim 1,
wherein the first region is a region through which light bundles constituting the first laser emitted from the first laser emitting unit pass.

16. The LiDAR device of claim 1,
wherein a center of curvature defined by a curvature of the first region of the first optical window is located between the first region and the laser emitting array.

17. The LiDAR device of claim 1,
wherein a center of curvature defined by a curvature of the first region of the first optical window is located inside the transmission optic.
